(19) United States
(12) Patent Application Publication
(10) Pub. No.: US 2024/0206147 A1
(43) Pub. Date: Jun. 20, 2024

(54) SEMICONDUCTOR STRUCTURES AND METHODS FOR FORMING THE SAME

(71) Applicant: YANGTZE MEMORY TECHNOLOGIES CO., LTD., Wuhan (CN)

(72) Inventors: Hao Zhang, Wuhan (CN); Bingjie Yan, Wuhan (CN); Ya Wang, Wuhan (CN); Wenyu Hua, Wuhan (CN)

(21) Appl. No.: 18/214,127

(22) Filed: Jun. 26, 2023

Related U.S. Application Data
(63) Continuation of application No. PCT/CN2023/093907, filed on May 12, 2023.
(60) Provisional application No. 63/348,354, filed on Jun. 2, 2022.

(51) Int. Cl. H10B 12/00

(52) U.S. Cl. CPC H10B 12/05; H10B 12/315

(57) ABSTRACT

A semiconductor structure and method for manufacturing thereof are provided. The semiconductor structure includes a vertical transistor. The vertical transistor includes a semiconductor body extending in a first direction. The semiconductor body includes a source/drain at one end of the semiconductor body. The vertical transistor also includes a gate structure coupled to at least one side of the semiconductor body. The gate structure includes a gate dielectric and a gate electrode. The vertical transistor further includes a silicide. At least part of the silicide is above the source/drain. An area of the silicide is larger than an area of a first surface of the source/drain. The first surface is vertical to the first direction.

### CROSS-REFERENCE TO RELATED APPLICATIONS

This application is a continuation of International Application No. PCT/CN2023/093907, filed on May 12, 2023, entitled “SEMICONDUCTOR STRUCTURES AND METHODS FOR FORMING THE SAME,” which claims the benefit of priority to U.S. Provisional Application No. 63/348,354, filed on Jun. 2, 2022, both of which are incorporated herein by reference in their entireties.

### BACKGROUND

The present disclosure relates to semiconductor structures and methods for forming the same.

When the feature size of semiconductor technology shrinks below deep submicron, the width of the source and drain areas of transistors continues to decrease, resulting in an increase in the series resistance of the source and drain areas of the device. In addition, the size of the interconnect contact holes at the back end also continues to shrink, and as the size of the contact holes decreases, the contact resistance of individual contact holes also increases. To reduce the series resistance and contact resistance of the source and drain areas, a metal silicide is formed on the active region.

### SUMMARY

In one aspect, a semiconductor structure including a vertical transistor is provided. The vertical transistor includes a semiconductor body extending in a first direction. The semiconductor body includes a source/drain at one end of the semiconductor body. The vertical transistor also includes a gate structure coupled to at least one side of the semiconductor body. The gate structure includes a gate dielectric and a gate electrode. The vertical transistor further includes a silicide. At least part of the silicide is above the source/drain. An area of the silicide is larger than an area of a first surface of the source/drain. The first surface is vertical to the first direction.

In some implementations, the silicide at least partially covers at least one second surface of the source/drain, and the at least one second surface is vertical to the first surface.

In some implementations, the semiconductor structure further includes an epitaxial structure formed between the source/drain and the silicide.

In some implementations, the semiconductor structure further includes a first isolation layer surrounding the semiconductor body. The first surface of the source/drain is exposed from the first isolation layer, and the epitaxial structure covers the first surface of the source/drain.

In some implementations, the semiconductor structure further includes a first isolation layer surrounding the semiconductor body. The first surface and at least part of a second surface of the source/drain is exposed from the first isolation layer, and the epitaxial structure covers the first surface and at least part of the second surface of the source/drain.

In some implementations, the semiconductor structure further includes a second isolation layer surrounding the epitaxial structure. A first top surface of the epitaxial structure is exposed from the second isolation layer, and the silicide covers the first top surface of the epitaxial structure.

In some implementations, the semiconductor structure further includes a second isolation layer surrounding the silicide, and a second top surface of the silicide is exposed from the second isolation layer.

In some implementations, the silicide is isolated from the gate structure, and a minimal distance between the silicide and the gate structure is larger than a threshold distance.

In some implementations, the semiconductor structure further includes a landing layer covering the silicide and a metal contact extending through the landing layer and in contact with a second top surface of the silicide. An area of a surface of the metal contact in touch with the silicide is smaller than or equal to the area of the second top surface of the silicide.

In some implementations, the silicide includes elements of Titanium (Ti), Cobalt (Co), or nickel platinum alloy (NiPt), and the silicide comprises titanium disilicide (TiSi₂) in a face-centered orthorhombic structure (C54 phase).

In another aspect, a semiconductor system is provided. The semiconductor system includes a semiconductor structure with a plurality of vertical transistors and a memory controller coupled to the semiconductor structure and configured to control the semiconductor structure. Each vertical transistor of at least part of the plurality of vertical transistors includes a semiconductor body extending in a first direction. The semiconductor body includes a source/drain at one end of semiconductor body. The semiconductor body also includes a gate structure coupled to at least one side of the semiconductor body. The gate structure includes a gate dielectric and a gate electrode. The semiconductor body further includes a silicide. At least part of the silicide is above the source/drain, and an area of the silicide is larger than an area of a first surface of the source/drain. The first surface is vertical to the first direction.

In some implementations, the silicide at least partially covers at least one second surface of the source/drain, the at least one second surface is vertical to the first surface.

In some implementations, the semiconductor system further includes an epitaxial structure formed between the source/drain and the silicide.

In some implementations, the semiconductor system further includes a first isolation layer surrounding the semiconductor body. The first surface of the source/drain is exposed from the first isolation layer, and the epitaxial structure covers the first surface of the source/drain.

In some implementations, the semiconductor system further includes a first isolation layer surrounding the semiconductor body. The first surface and at least part of a second surface of the source/drain are exposed from the first isolation layer, and the epitaxial structure covers the first surface and at least part of the second surface of the source/drain.

In some implementations, the semiconductor system further includes a second isolation layer surrounding the epitaxial structure. A first top surface of the epitaxial structure is exposed from the second isolation layer, and the silicide covers the first top surface of the epitaxial structure.

In some implementations, the semiconductor system further includes a second isolation layer surrounding the silicide, and a second top surface of the silicide is exposed from the second isolation layer.

In some implementations, the silicide is isolated from the gate structure, and a minimal distance between the silicide and the gate structure is larger than a threshold distance.

In some implementations, the semiconductor system further includes a landing layer covered the silicide and a metal contact extending through the landing layer and in contact with the silicide. An area of a surface of the metal contact in touch with the silicide is smaller than or equal to the area of the silicide.

In some implementations, the silicide includes elements of Titanium (Ti), Cobalt (Co), or nickel platinum alloy (NiPt), and the silicide comprises titanium disilicide (TiSi₂) in a face-centered orthorhombic structure (C54 phase).

In another aspect, a method for forming a semiconductor structure is provided. The method includes following: forming a semiconductor body of the semiconductor structure extending in a first direction from a substrate; forming a gate structure on at least one side of the semiconductor body; forming a source/drain at a distal end of the semiconductor body away from the substrate; forming a first isolation layer surrounding the semiconductor body and the gate structure; and forming a silicide. At least part of the silicide is above the source/drain. An area of the silicide is larger than an area of a first surface of the source/drain, the first surface being vertical to the first direction.

In some implementations, a first surface and at least part of a second surface of the source/drain are exposed from the first isolation layer, the second surface being vertical to the first surface, and the silicide is formed on the first surface and at least part of a second surface of the source/drain.

In some implementations, after forming the silicide, the method further includes forming a second isolation layer surrounding the silicide, and a first surface of the silicide is exposed from the second isolation layer.

In some implementations, forming the silicide includes depositing a metal layer covering the first surface and at least part of a second surface of the source/drain exposed from the first isolation layer, and heating the metal layer to form the silicide by reaction between the metal layer and the source/drain.

In some implementations, heating the metal layer includes performing a first rapid thermal annealing (RTA) on the metal layer at a first temperature lower than a threshold temperature.

In some implementations, heating the metal layer further includes performing a second RTA on the metal layer at a second temperature higher than the threshold temperature.

In some implementations, forming the silicide further includes depositing a metal nitride on the metal layer before performing the first RTA.

In some implementations, after forming a silicide, further includes following: forming a landing layer covered the silicide; forming a through hole on the landing layer to expose the silicide, an area of a cross-section of the through hole is larger than or equal to an area of a second top surface of the silicide; and forming a source/drain contact in touch with the silicide through a metal contact formed in the through hole.

In some implementations, a first surface of the source/drain being exposed from the first isolation layer. The method further includes growing an epitaxial structure from the first surface of the source/drain before forming the silicide. An area of a first surface of the epitaxial structure is larger than an area of the first surface of the source/drain. The silicide is formed based on the epitaxial structure.

In some implementations, after forming a first isolation layer, the method further includes etching the first isolation layer to expose at least part of a second surface of the source/drain, the second surface of the source/drain is vertical to the first surface of the source/drain.

In some implementations, growing the epitaxial structure further includes growing the epitaxial structure from the at least part of the second surface of the source/drain exposed from the first isolation layer.

In some implementations, after growing the epitaxial structure, further includes forming a second isolation layer covering the epitaxial structure before forming the silicide, the second isolation layer aligns with the epitaxial structure and a first top surface of the epitaxial structure is exposed from the second isolation layer.

In some implementations, after forming the silicide, further includes forming a second isolation layer covering the silicide, the second isolation layer aligns with the silicide and a second top surface of the silicide is exposed from the second isolation layer.

In some implementations, forming the silicide includes forming a second isolation layer covering the epitaxial structure, the second isolation layer aligning with the epitaxial structure. At least a first surface of the epitaxial structure is exposed from the second isolation layer. Forming the silicide further includes depositing a metal layer at least covering the first surface of the epitaxial structure exposed from the second isolation layer and heating the metal layer to form the silicide.

In some implementations, heating the metal layer includes performing a first rapid thermal annealing (RTA) on the metal layer at a first temperature lower than a threshold temperature.

In some implementations, heating the metal layer further includes performing a second RTA on the metal layer at a second temperature higher than the threshold temperature.

In some implementations, forming the silicide further includes depositing a metal nitride on the metal layer before performing the first RTA.

In some implementations, after forming a silicide, further includes following: forming a landing layer covering the silicide; forming a through hole on the landing layer to expose the silicide, an area of a cross-section of the through hole is larger than or equal to an area of a second top surface of the silicide; and forming a source/drain contact in touch with the silicide through a metal contact formed in the through hole.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1 illustrates a perspective view of a vertical transistor, according to some aspects of the present disclosure.

FIG. 2 illustrates a schematic diagram of a memory device including peripheral circuits and an array of memory cells each having a vertical transistor, according to some aspects of the present disclosure.

FIG. 3A illustrates a schematic circuit diagram of a memory device including peripheral circuits and an array of dynamic random-access memory (DRAM) cells, according to some aspects of the present disclosure.

FIG. 3B illustrates a schematic circuit diagram of a memory device including peripheral circuits and an array of phase-change memory (PCM) cells, according to some aspects of the present disclosure.

FIG. 4 illustrates a block diagram of an exemplary system having a memory device, according to some aspects of the present disclosure.

FIG. 5A illustrates a plan view of an array of vertical transistors in a semiconductor device, according to some aspects of the present disclosure.

FIG. 5B illustrates a perspective view of a semiconductor structure of vertical transistors.

FIG. 5C illustrates a graph between a silicide transformation temperature T1, an agglomeration temperature T2 and a linewidth of the silicide according to some aspects of the present disclosure.

FIGS. 6A-6P illustrate a fabrication process for forming a semiconductor structure, according to some aspects of the present disclosure.

FIG. 6Q illustrates a perspective view of the semiconductor structure illustrated in FIGS. 6A-6P, according to some aspects of the present disclosure.

FIGS. 6R-6S illustrate another fabrication process for forming a semiconductor structure, according to some aspects of the present disclosure.

FIG. 6T illustrates a perspective view of the semiconductor structure illustrated in FIGS. 6R-6S, according to some aspects of the present disclosure.

FIGS. 7A-7E illustrate a fabrication process for forming a semiconductor device in FIG. 7, according to some aspects of the present disclosure.

FIG. 7F illustrates a perspective view of the semiconductor structure illustrated in FIGS. 7A-7D, according to some aspects of the present disclosure.

FIGS. 7G-7H illustrate another fabrication process for forming the semiconductor structure, according to some aspects of the present disclosure.

FIGS. 8A-8B illustrate a fabrication process for forming the semiconductor structure, according to some aspects of the present disclosure.

FIG. 8C illustrates a perspective view of the semiconductor structure illustrated in FIGS. 8A-8B, according to some aspects of the present disclosure.

FIG. 9 illustrates a flowchart of a method for forming a semiconductor device including vertical transistors, according to some aspects of the present disclosure.

FIG. 10 illustrates a flowchart of a method for forming another semiconductor device including vertical transistors, according to some aspects of the present disclosure.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors are used as the switch or selecting devices in the memory cells of some memory devices, such as DRAM, PCM, and ferroelectric DRAM (FRAM). However, the planar transistors commonly used in existing memory cells usually have a horizontal structure with buried word lines in the substrate and bit lines above the substrate. Since the source and drain of a planar transistor are disposed laterally at different locations, which increases the area occupied by the transistor. The design of planar transistors also complicates the arrangement of interconnected structures, such as word lines and bit lines, coupled to the memory cells, for example, limiting the pitches of the word lines and/or bit lines, thereby increasing the fabrication complexity and reducing the production yield.

When the feature size of semiconductor technology shrinks below deep submicron, the width of the source and drain areas of transistors continues to decrease, resulting in an increase in the series resistance of the source and drain areas of the device. In addition, the continuing decrease in the size of the interconnect contact holes results in an increase in the contact resistance of each contact hole. For technology platforms with a feature size equal to or smaller than 0.25 μm, the size of the contact holes is smaller than 0.32 μm. As a result, the contact resistance of a single contact hole has increased to more than 200 ohms. To reduce the contact resistance of source/drain, a metal silicide is formed on source/drain by reacting metals (such as Titanium (Ti), Cobalt (Co), or nickel platinum alloy (NiPt)) with silicon in direct contact with source/drain to form silicide. Silicide can reduce the contact resistance of source/drain and improve the speed of the circuit by reducing the resistor-capacitance (RC) delay of the circuit.

Taking Ti-silicide as an example, Ti-silicide has two crystal structures: a body-centered orthorhombic crystal structure (C49 phase) and a face-centered orthorhombic crystal structure (C54 phase). C54 phase silicide has a low resistance and a stable state. Generally, the temperature for generating C49 phase silicide is lower than the temperature for generating C54 phase silicide. However, as the thickness/linewidth of silicide decreases with the decrease of the feature size of the process, the temperature for Ti-silicide to transform from C49 phase to C54 phase increases, while the temperature for the agglomeration of C54 phase decreases. Once the temperature at which C54 phase undergoes agglomeration is lower than the temperature for the transformation from C49 phase to C54 phase, Ti-silicide will directly undergo agglomeration with C49 phase, resulting in the disappearance of the low-resistance metal silicide in C54 phase. Therefore, Ti-silicide cannot be used in processes with a feature size smaller than 0.2 μm.

To address one or more of the aforementioned issues, the present disclosure introduces a semiconductor structure and method for manufacturing thereof to increase the linewidth of silicide by increasing the area on which the silicide is formed. According to some aspects of the present disclosure, an epitaxial structure with a larger surface area is formed on the source/drain. As the silicide is formed on the surface of the epitaxial structure, the area of the silicide is increased. According to some aspects of the present disclosure, in addition to the top surface of the source/drain, the area where silicide is formed is expanded to include the side surfaces of the source/drain. At least part of the side surface of the source/drain is exposed to form the silicide by removing part of the isolation layer surrounding the source/drain. As the linewidth of the silicide increased, the limitation of the feature size is eliminated, and silicide can be applied to processes with a feature size smaller than 0.2 μm.

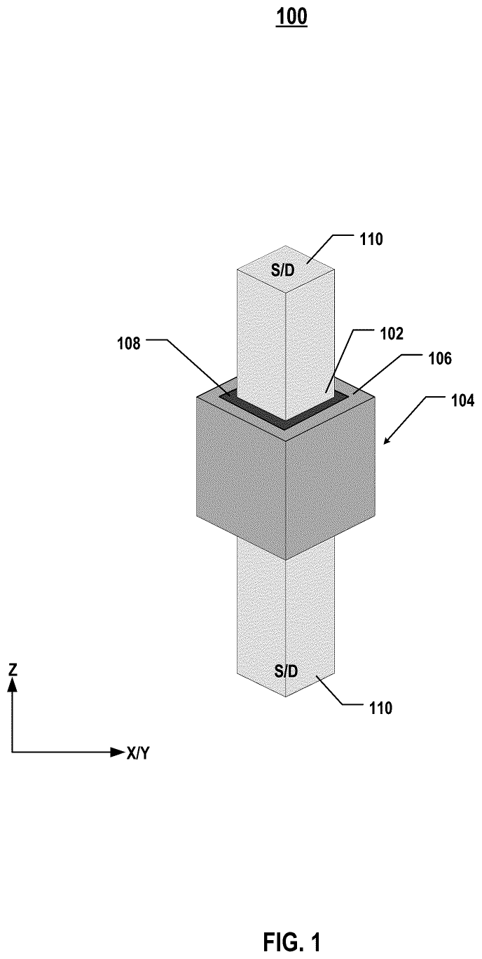

FIG. 1 illustrates a perspective view of a vertical transistor 100, according to some aspects of the present disclosure. In some implementations, different from planar transistors in which the active regions are formed in the substrate, vertical transistor 100 includes a semiconductor body 102 extending vertically (in the z-direction) above the substrate (not shown). That is, semiconductor body 102 can extend above the top surface of the substrate to allow channels to be formed not only at the top surface of semiconductor body 102, but also at one or more side surfaces thereof. It is noted that x, y, and z axes are included in FIG. 1 to further illustrate the spatial relationship of the components in a semiconductor device having vertical transistor 100. The substrate of the semiconductor device includes two lateral surfaces extending laterally in the x-y plane: a top surface on the front side of the wafer on which the semiconductor device can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of the semiconductor device is determined relative to the substrate of the semiconductor device in the z-direction (the vertical direction perpendicular to the x-y plane, e.g., the thickness direction of the substrate) when the substrate is positioned in the lowest plane of the semiconductor device in the z-direction. The same notion for describing the spatial relationships is applied throughout the present disclosure.

As shown in FIG. 1, for example, semiconductor body 102 can have a cuboid shape to expose four sides thereof. It is understood that semiconductor body 102 may have any suitable three-dimensional (3D) shape, such as polyhedron shapes or a cylinder shape. That is, the cross-section of semiconductor body 102 in the plan view (e.g., in the x-y plane) can have a square shape, a rectangular shape (or a trapezoidal shape), a circular (or an oval shape), or any other suitable shapes. It is understood that consistent with the scope of the present disclosure, for semiconductor bodies that have a circular or oval shape of their cross-sections in the plan view, the semiconductor bodies may still be considered as having multiple sides, such that the gate structures are in contact with more than one side of the semiconductor bodies. As described below with respect to the fabrication process, semiconductor body 102 can be formed from the substrate (e.g., by etching) and thus, has the same semiconductor material (e.g., silicon crystalline silicon) as the substrate (e.g., a silicon substrate).

As shown in FIG. 1, vertical transistor 100 can also include a gate structure 104 in contact with one or more sides of semiconductor body 102, e.g., in one or more planes of the side surface(s) of the active region. In other words, the active region of vertical transistor 100, e.g., semiconductor body 102, can be at least partially surrounded by gate structure 104. Gate structure 104 can include a gate dielectric 108 over one or more sides of semiconductor body 102, e.g., in contact with four side surfaces of semiconductor body 102, as shown in FIG. 1. Gate structure 104 can also include a gate electrode 106 over and in contact with gate dielectric 108. Gate dielectric 108 can include any suitable dielectric materials, such as silicon oxide, silicon nitride, silicon oxynitride, or high-k dielectrics. As used herein, high-k dielectric materials may include any dielectrics having a dielectric constant, or k-value, higher than that of silicon nitride (k>7). For example, gate dielectric 108 may include silicon oxide, which is a form of gate oxide. Gate electrode 106 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 106 may include doped polysilicon, which is a form of a gate poly. In some implementations, gate electrode 106 includes multiple conductive layers, such as a W layer over a TiN layer. It is understood that in a semiconductor device having vertical transistors 100, gate electrode 106 and a word line (not shown in FIG. 1) may be a continuous conductive structure in some examples. In other words, gate electrode 106 may be viewed as part of a word line (not shown in FIG. 1) that forms gate structure 104, or the word line may be viewed as the extension of gate electrode 106 to be coupled to peripheral circuits.

As shown in FIG. 1, vertical transistor 100 can further include a pair of a source and a drain 110 (S/D, dope regions, a.k.a., source electrode and drain electrode) formed at the two terminals (ends) of semiconductor body 102 in the vertical direction (the z-direction), respectively. Source and drain 110 can be doped with any suitable P-type dopants, such as boron (B) or Gallium (Ga), or any suitable N-type dopants, such as phosphorus (P) or arsenic (As). Source and drain 110 can be separated by gate structure 104 in the vertical direction (the z-direction). In other words, gate structure 104 is formed vertically between source and drain 110. As a result, one or more channels (not shown) of vertical transistor 100 can be formed in semiconductor body 102 vertically between source and drain 110 when a gate voltage applied to gate electrode 106 of gate structure 104 is above the threshold voltage of vertical transistor 100. That is, each channel of vertical transistors 100 is also formed in the vertical direction along which semiconductor body 102 extends, according to some implementations.

In some implementations, as shown in FIG. 1, vertical transistor 100 is a multi-gate transistor. That is, gate structure 104 can be in contact with more than one side of semiconductor body 102 (e.g., four sides in FIG. 1) to form more than one gate, such that more than one channel can be formed between source and drain 110 in operation. That is, different from the planar transistor that includes only a single planar gate (and results in a single planar channel), vertical transistor 100 shown in FIG. 1 can include multiple vertical gates on multiple sides of semiconductor body 102 due to the 3D structure of semiconductor body 102 and gate structure 104 that surrounds the multiple sides of semiconductor body 102. As a result, compared with planar transistors, vertical transistor 100 shown in FIG. 1 can have a larger gate control area to achieve better channel control with a smaller subthreshold swing. Since the channel is fully depleted, the leakage current (_{Ioff}) of vertical transistor 100 can be significantly reduced as well.

It is understood that although vertical transistor 100 is shown as a multi-gate transistor in FIG. 1, the vertical transistors disclosed herein may also include single-gate transistors as described below in detail. That is, gate structure 104 may be in contact with a single side of semiconductor body 102, for example, for the purpose of increasing the transistor density. It is also understood that although gate dielectric 108 is shown as being separate (a separate structure) from other gate dielectrics of adjacent vertical transistors (not shown), gate dielectric 108 may be part of a continuous dielectric layer having multiple gate dielectrics of vertical transistors.

In planar transistors and some lateral multiple-gate transistors (e.g., FinFET), the active regions, such as semiconductor bodies (e.g., Fins), extend laterally (in the x-y plane), and the source and the drain are disposed at different locations in the same lateral plane (the x-y plane). In contrast, in vertical transistor 100, semiconductor body 102 extends vertically (in the z-direction), and source and drain 110 are disposed in the different lateral planes, according to some implementations. In some implementations, source and drain 110 are formed at two terminals of semiconductor body 102 in the vertical direction (the z-direction), respectively, thereby overlapping in the plan view. As a result, the area (in the x-y plane) occupied by vertical transistor 100 can be reduced compared with planar transistors and lateral multiple-gate transistors. Also, the metal wiring coupled to vertical transistors 100 can be simplified as well since the interconnects can be routed in different planes.

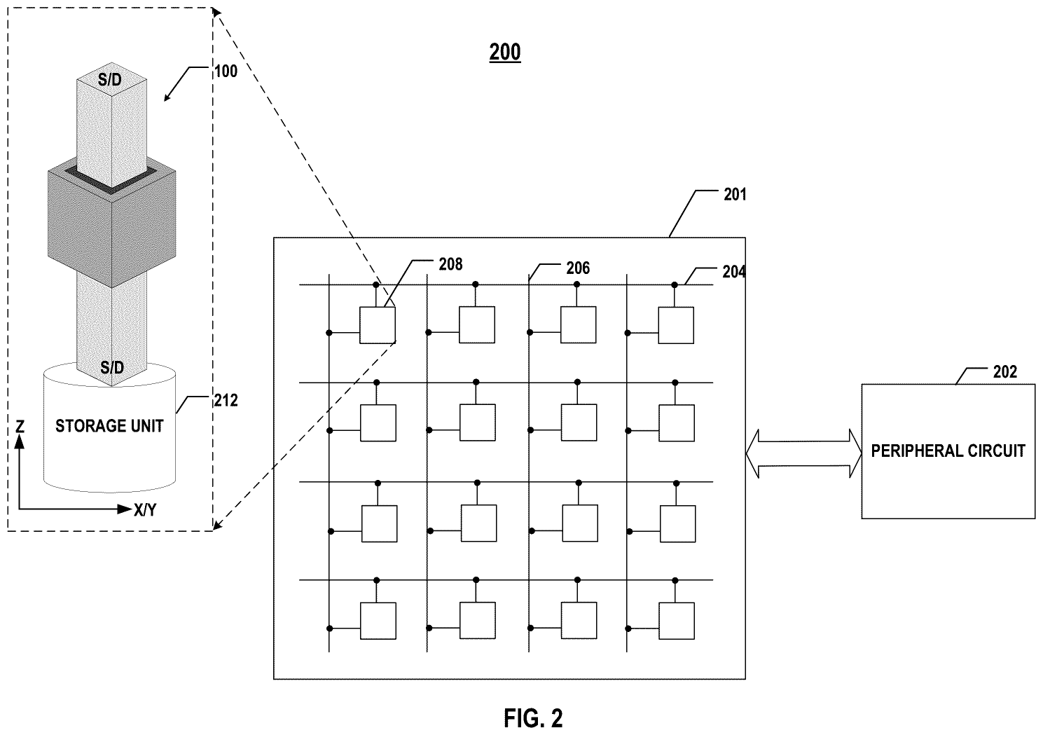

FIG. 2 illustrates a schematic diagram of a memory device 200 including peripheral circuits and an array of memory cells each having vertical transistor 100, according to some aspects of the present disclosure. Memory device 200 can include a memory cell array 201 and peripheral circuits 202 coupled to memory cell array 201. Memory cell array 201 can be any suitable memory cell array in which each memory cell 208 includes vertical transistor 100 and a storage unit 212 coupled to vertical transistor 100. In some implementations, memory cell array 201 is a DRAM cell array, and storage unit 212 is a capacitor for storing charge as the binary information stored by the respective DRAM cell. In some implementations, memory cell array 201 is a PCM cell array, and storage unit 212 is a PCM element (e.g., including chalcogenide alloys) for storing binary information of the respective PCM cell based on the different resistivities of the PCM element in the amorphous phase and the crystalline phase. In some implementations, memory cell array 201 is a ferroelectric RAM (FRAM) cell array, and storage unit 212 is a ferroelectric capacitor for storing binary information of the respective FRAM cell based on the switch between two polarization states of ferroelectric materials under an external electric field.

As shown in FIG. 2, memory cells 208 can be arranged in a two-dimensional (2D) array having rows and columns. Memory device 200 can include word lines 204 coupling peripheral circuits 202 and memory cell array 201 for controlling the switch of vertical transistors 100 in memory cells 208 located in a row, as well as bit lines 206 coupling peripheral circuits 202 and memory cell array 201 for sending data to and/or receiving data from memory cells 208 located in a column. That is, each word line 204 is coupled to a respective row of memory cells 208, and each bit line is coupled to a respective column of memory cells 208.

Consistent with the scope of the present disclosure, vertical transistors 100, such as vertical metal-oxide-semiconductor field-effect transistors (MOSFETs), can replace the planar transistors as the pass transistors of memory cells 208 to reduce the area occupied by the pass transistors, the coupling capacitance, as well as the interconnect routing complexity. For example, bit lines 206 and storage units 212 may be formed on opposite sides of vertical transistor 100. In one example, bit line 206 may be coupled to source or drain 110 at the upper end of semiconductor body 102, while storage unit 212 may be coupled to the other source or drain 110 at the lower end of semiconductor body 102.

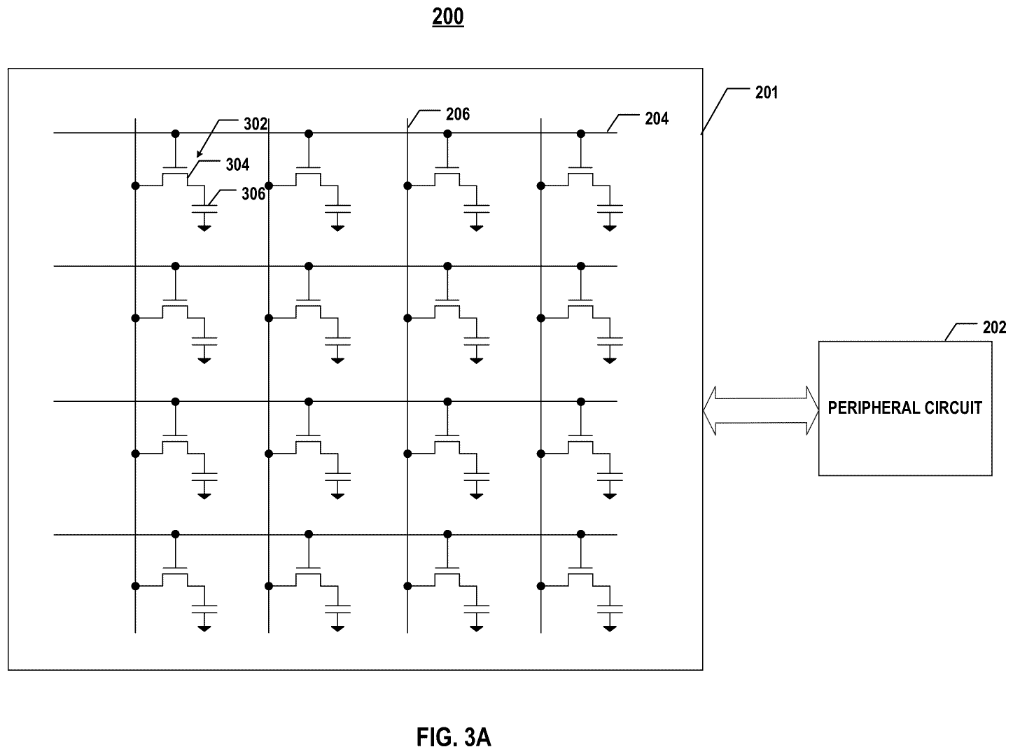

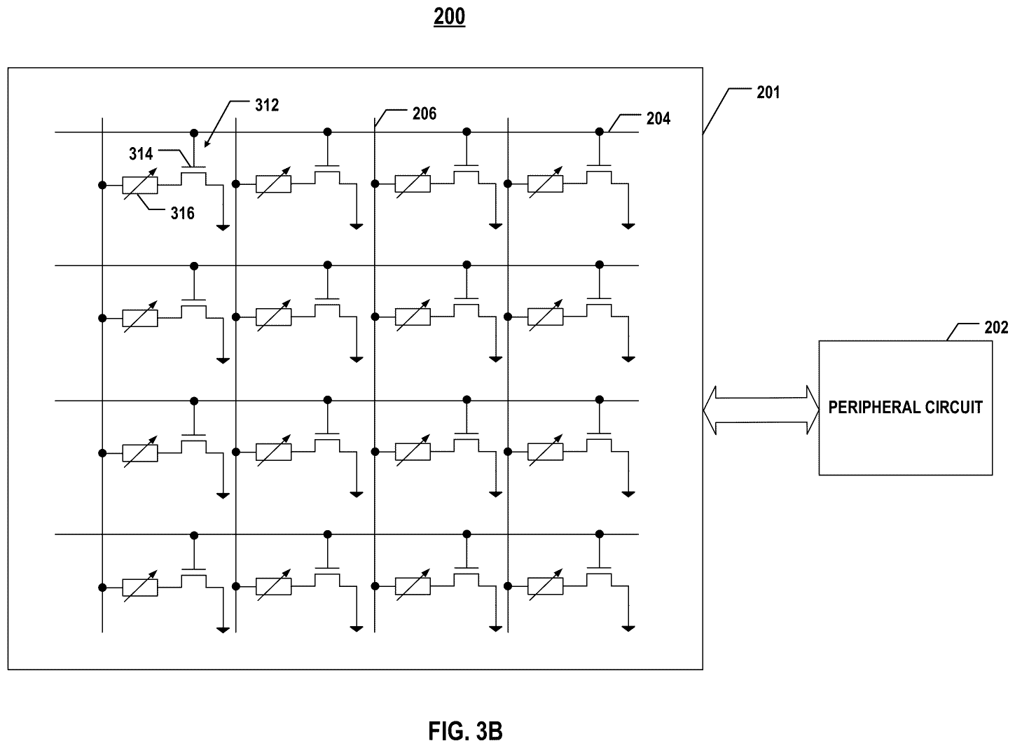

As shown in FIG. 2, storage unit 212 can be coupled to source or drain 110 of vertical transistor 100. Storage unit 212 can include any devices that are capable of storing binary data (e.g., 0 and 1), including but not limited to, capacitors for DRAM cells and FRAM cells, and PCM elements for PCM cells. In some implementations, vertical transistor 100 controls the selection and/or the state switch of the respective storage unit 212 coupled to vertical transistor 100. In some implementations as shown in FIG. 3, each memory cell 208 is a DRAM cell 302 including a transistor 304 (e.g., implementing using vertical transistors 100 in FIGS. 1 and 2) and a capacitor 306 (e.g., an example of storage unit 212 in FIG. 2). The gate of transistor 304 (e.g., corresponding to gate electrode 106) may be coupled to word line 204, one of the source and the drain of transistor 304 may be coupled to bit line 206, the other one of the source and the drain of transistor 304 may be coupled to one electrode of capacitor 306, and the other electrode of capacitor 306 may be coupled to the ground. In some implementations as shown in FIG. 3B, each memory cell 208 is a PCM cell 312 including a transistor 314 (e.g., implementing using vertical transistors 100 in FIGS. 1 and 2) and a PCM element 316 (e.g., an example of storage unit 212 in FIG. 2). The gate of transistor 314 (e.g., corresponding to gate electrode 106) may be coupled to word line 204, one of the source and the drain of transistor 314 may be coupled to the ground, the other one of the source and the drain of transistor 314 may be coupled to one electrode of PCM element 316, and the other electrode of PCM element 316 may be coupled to bit line 206.

Peripheral circuits 202 (a.k.a. control and sensing circuits) can be coupled to memory cell array 201 through bit lines 206, word lines 204, and any other suitable metal wirings. Peripheral circuits 202 can include any suitable digital, analog, and/or mixed-signal circuits used for facilitating the operations of memory cell array 201 by applying and sensing voltage signals and/or current signals through word lines 204 and bit lines 206 to and from each memory cell 208. For example, peripheral circuit 202 can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). Peripheral circuits 202 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations.

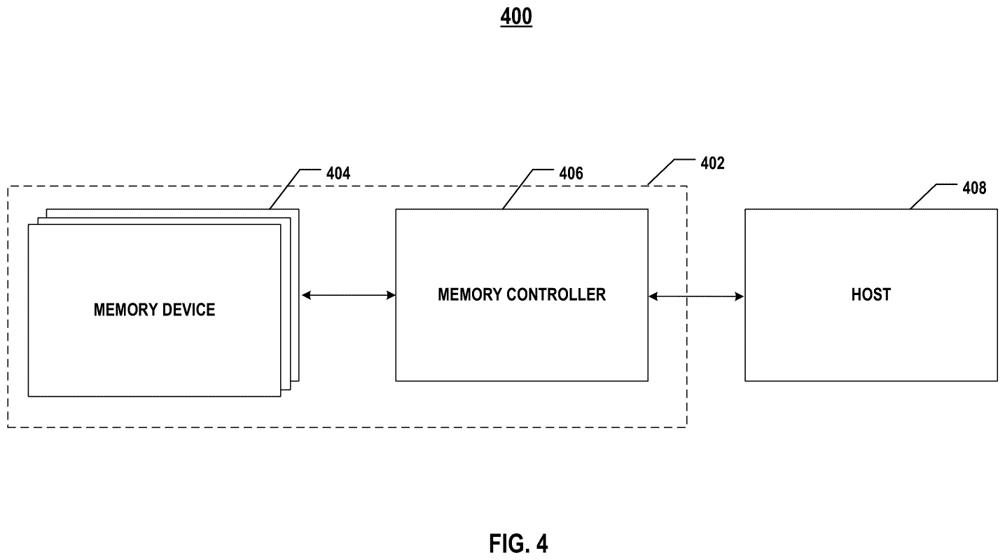

FIG. 4 illustrates a block diagram of a system 400 having a memory device, according to some aspects of the present disclosure. System 400 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 4, system 400 can include a host 408 and a memory system 402 having one or more memory devices 404 and a memory controller 406. Host 408 can be a processor of an electronic device, such as a central processing unit (CPU), or a system-on-chip (SoC), such as an application processor (AP). Host 408 can be configured to send or receive the data to or from memory devices 404.

Memory controller 406 is coupled to memory device 404 and host 408 and is configured to control memory device 404, according to some implementations. Memory controller 406 can manage the data stored in memory device 404 and communicate with host 408. Memory controller 406 can be configured to control operations of memory device 404, such as read, write, and refresh operations. Memory controller 406 can also be configured to manage various functions with respect to the data stored or to be stored in memory device 404 including, but not limited to refresh and timing control, command/request translation, buffer and schedule, and power management. In some implementations, memory controller 406 is further configured to determines the maximum memory capacity that the computer system can use, the number of memory banks, memory type and speed, memory particle data depth and data width, and other important parameters. Any other suitable functions may be performed by memory controller 406 as well. Memory controller 406 can communicate with an external device (e.g., host 408) according to a particular communication protocol. For example, memory controller 406 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

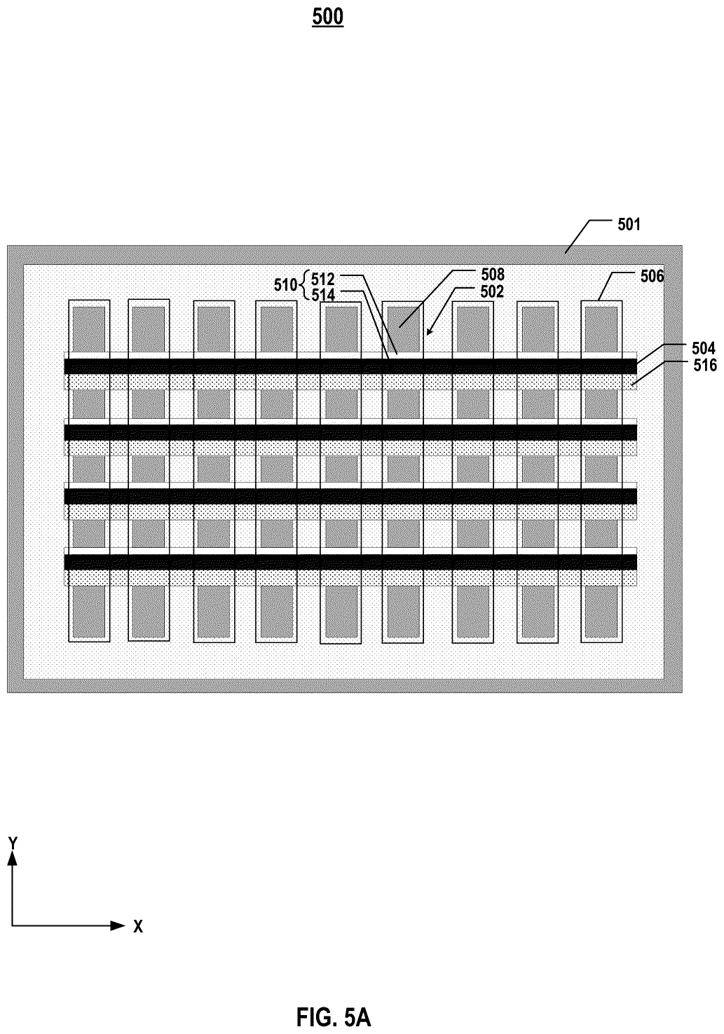

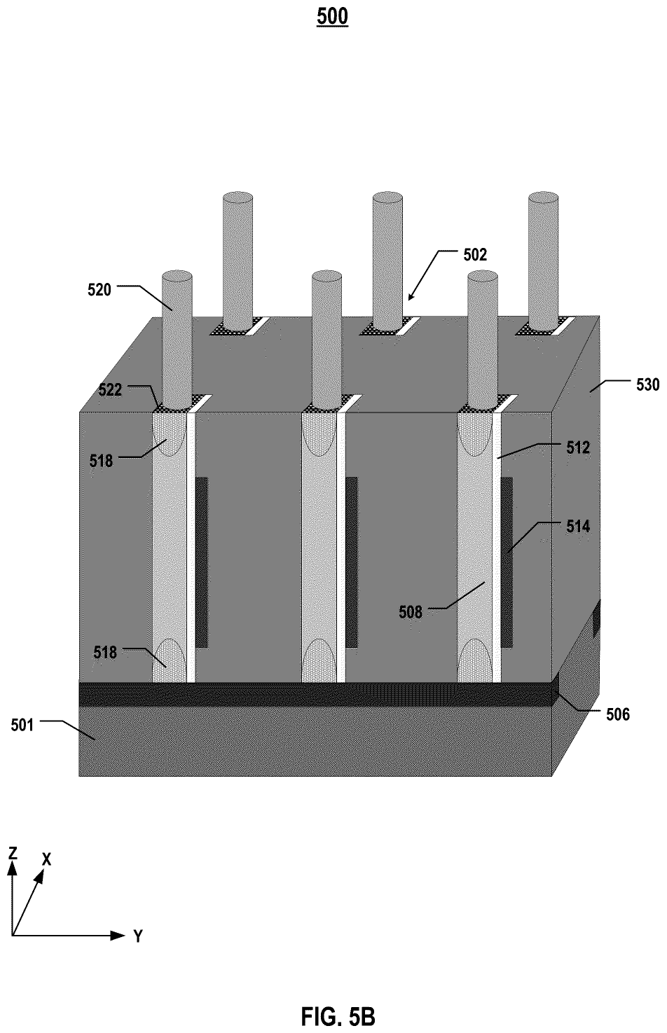

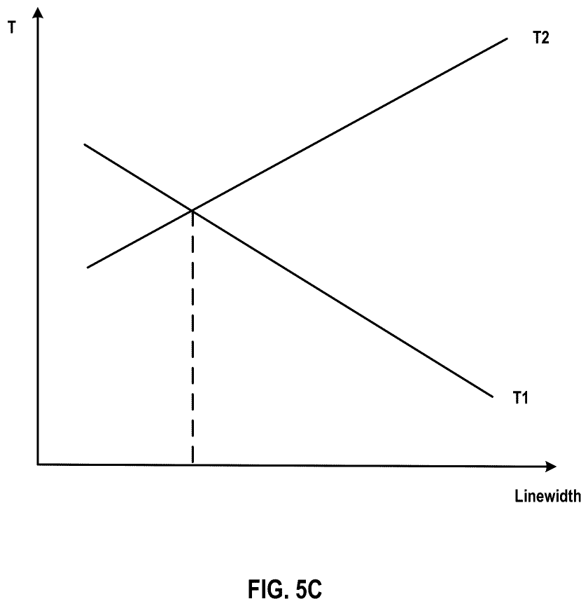

According to some aspects of the present disclosure, the vertical transistors disclosed herein include single-gate transistors (a.k.a. single-side gate transistors), which can have a thicker isolation layer (and/or with air gap) on the opposite side of the gate to reduce the coupling between adjacent vertical transistors. According to some aspects of the present disclosure, the vertical transistors disclosed herein include multi-gate transistors (for example, with dual-side, triple-side, or all-around gates), which can have a larger gate control area to achieve better channel control with a smaller subthreshold swing. The vertical transistors with different gate structure described herein are for illustrative purposes only and should not be interpreted as a limitation of the present disclosure. FIGS. 5A and 5B illustrate a plan view and a perspective view, respectively, of an array of vertical transistors 502 in a semiconductor device 500, according to some aspects of the present disclosure. As shown in FIGS. 5A and 5B, semiconductor device 500 can include a plurality of word lines 504 each extending in a first lateral direction (the x-direction, referred to herein as the word line direction). Semiconductor device 500 can also include a plurality of bit lines 506 each extending in a second lateral direction perpendicular to the first lateral direction (the y-direction, referred to herein as the bit line direction). It is understood that FIG. 5A does not illustrate a cross-section of semiconductor device 500 in the same lateral plane, and word lines 504 and bit lines 506 may be formed in different lateral planes for ease of routing as described below in detail.

Vertical transistors 502 can be formed at the intersections of word lines 504 and bit lines 506. In some implementations, each vertical transistor 502 includes a semiconductor body 508 and a gate structure 510. As shown in FIG. 5B, semiconductor body 508 can extend on a substrate 501 in the vertical direction (the z-direction) perpendicular to the first and second lateral directions. Vertical transistor 502 can be a single-gate transistor in which gate structure 510 is coupled to a single side (e.g., one of four sides in FIGS. 5A and 5B) of semiconductor body 508 (the active region in which channels are formed). As shown in FIGS. 5A and 5B, vertical transistor 502 is a single-gate transistor in which gate structure 510 abuts one side of semiconductor body 508 (having a rectangle or square-shaped cross-section) in the bit line direction (the y-direction) in the plan view. Gate structure 510 does not surround and contact the other three sides of semiconductor body 508, according to some implementations. Gate structure 510 can include a gate dielectric 512 abuts one side of semiconductor body 508 in the plan view, and a gate electrode 514 in contact with gate dielectric 512. In some implementations, gate dielectric 512 is positioned laterally between gate electrode 514 and semiconductor body 508 in the bit line direction (the y-direction).

As described above, gate electrode 514 may be part of word line 504, and word line 504 may be an extension of gate electrode 514. That is, gate electrodes 514 of adjacent vertical transistors 502 in the word line direction (the x-direction), e.g., in the same row, are continuous, e.g., parts of a continuous conductive layer having gate electrodes 514 and word line 504. Similarly, gate dielectrics 512 of adjacent vertical transistors 502 in the word line direction, e.g., in the same row, are continuous, e.g., parts of a continuous dielectric layer having gate dielectrics 512 and extending in the word line direction to abut vertical transistors 502 in the same row on the same side. Gate structures 510 can be thus viewed as parts of a continuous structure extending in the word line direction at which the continuous structure abuts vertical transistors 502 in the same row on the same side. Gate electrodes 514 and gate dielectrics 512 of a row of vertical transistors 502 are continuous in the word line direction, according to some implementations.

As shown in FIG. 5A, semiconductor device 500 can further include a plurality of parallel dielectric isolation layers 516 each extending in the word line direction (the x-direction). Each dielectric isolation layer 516 is positioned laterally between two adjacent rows of vertical transistors 502 in the bit line direction (the y-direction) to reduce the coupling effect between the adjacent rows of vertical transistors 502. As described below in detail, the thickness (the dimension in the bit line direction) of dielectric isolation layer 516 and/or whether air gaps being formed in dielectric isolation layer 516 can affect the effectiveness of coupling reduction.

Vertical transistor 502 further includes a source and a drain (both referred to as 518 as their locations may be interchangeable) disposed at the two ends (the upper end and lower end) of semiconductor body 508, respectively, in the vertical direction (the z-direction). In some implementations, one of source/drain 518 (e.g., at the upper end in FIG. 5B) is coupled to a capacitor (not shown) through metal connect 520, and the other one of source/drain 518 (e.g., at the lower end in FIG. 5B) is coupled to bit line 506. That is, vertical transistor 502 can have a first terminal in the positive z-direction and a second terminal opposite the first terminal in the negative z-direction, as shown in FIG. 5B. In some implementations, a metal bit line (e.g., bit line 506 made of a metal material) is coupled to the second terminal of vertical transistor 502. An additional structure is formed on source/drain 518 to reduce the contact resistance of source/drain 518. For example, high dose ion-implantation is implied to source/drain 518 to increase doping concentration of source/drain 518 to reduce resistance. In the present implementation, a metal silicide 522 is formed on the top surface of source/drain 518 to reduce the resistance of the source/drain 518. The additional structures described herein are for illustrative purposes only and should not be interpreted as a limitation of the present disclosure. Metal connect 520 is in contact with metal silicide 522. Metal silicide 522 can be WSi, CoSi, CuSi, AlSi, or any other suitable metal silicides having higher conductivities than doped silicon.

Still taking Ti-silicide as an example, as the silicide thickness decreases or the line width decreases, temperature T1 for the transformation of Ti-silicide from the C49 phase to the C54 phase increases, while temperature T2 for the agglomeration of the C54 phase decreases, which results in a critical point where T1=T2, as shown in FIG. 5C. In a situation where T2 is lower than T1, Ti-silicide will directly agglomerate after C49 phase, and C54 phase will disappear and lead to a metal silicide with high resistance. Therefore, only large-scale processes will use Ti-silicide technology, such as processes with feature sizes of 0.5 μm to 0.25 μm. In addition, for silicide, silicon that can participate in the reaction at the edge will be relatively less, so the thickness of the metal silicide formed at the edge will correspondingly become thinner. Thus, the resistance at the edge will increase accordingly. For processes with line widths below 0.18 μm, this characteristic will be very serious.

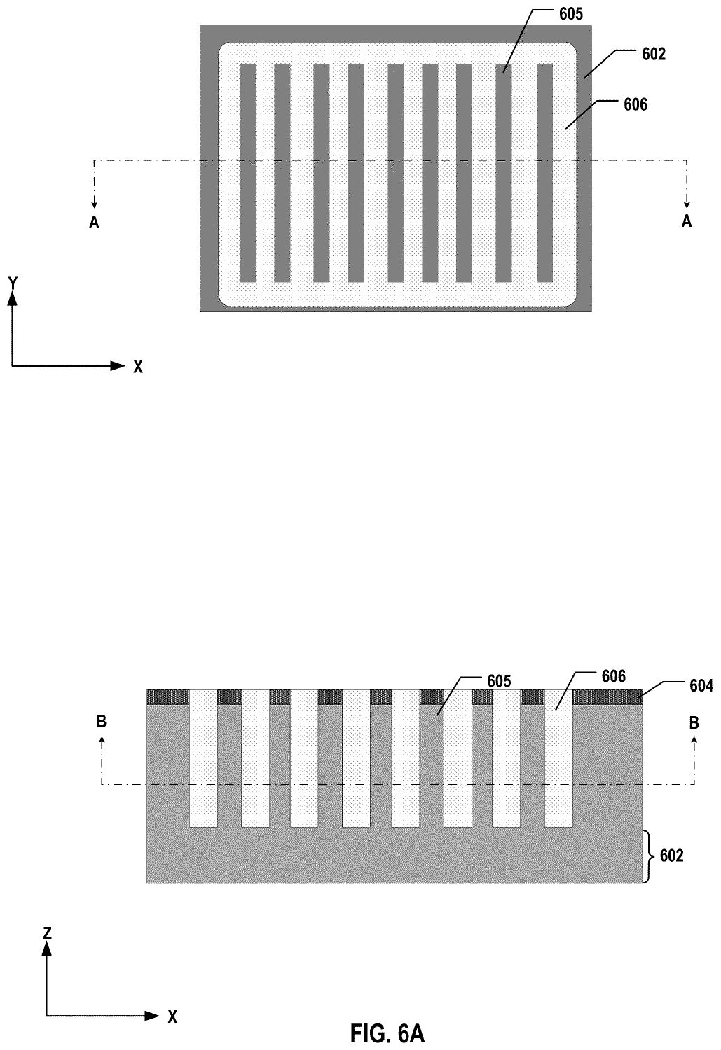

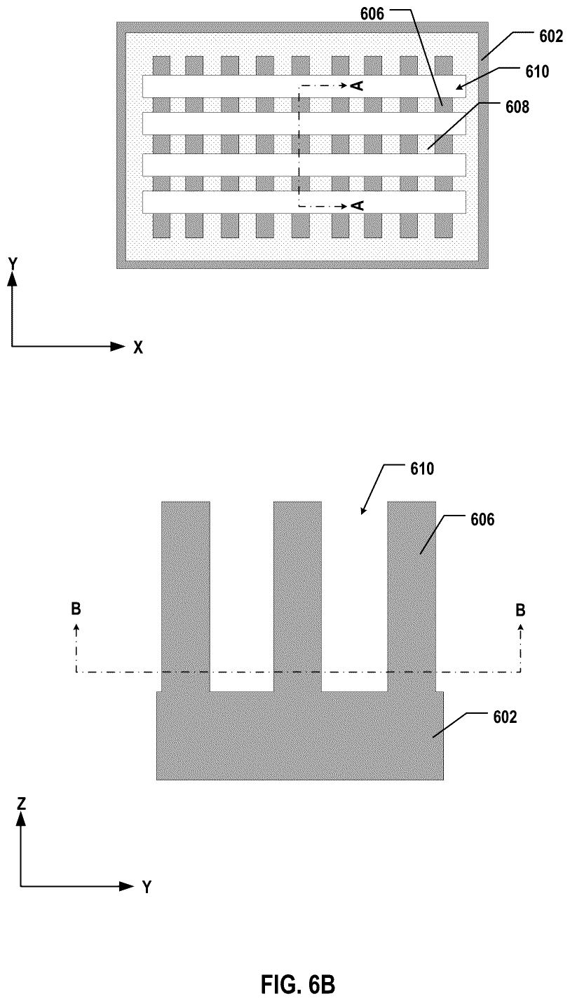

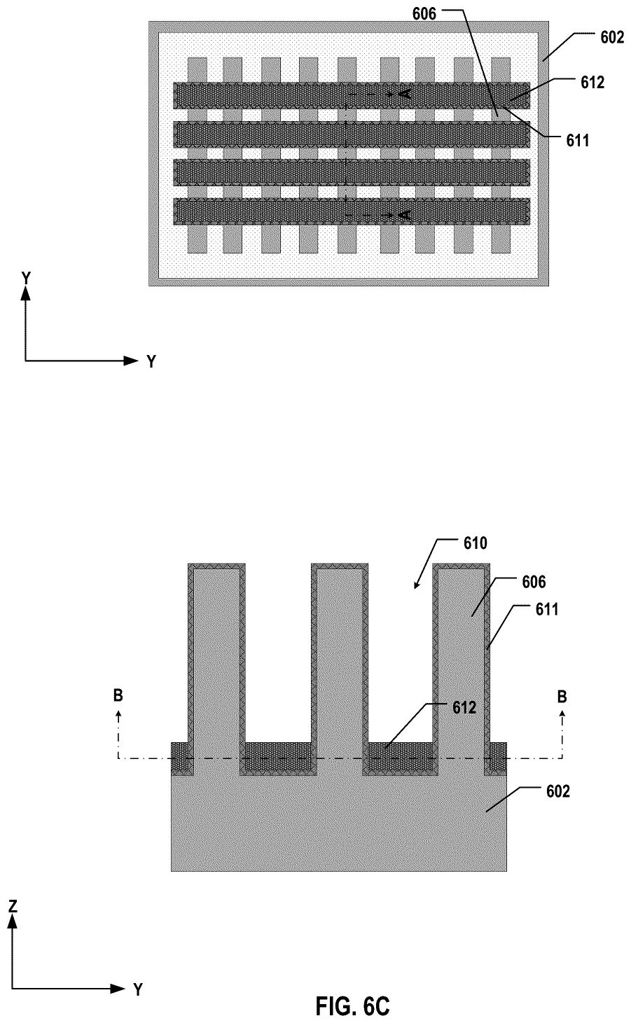

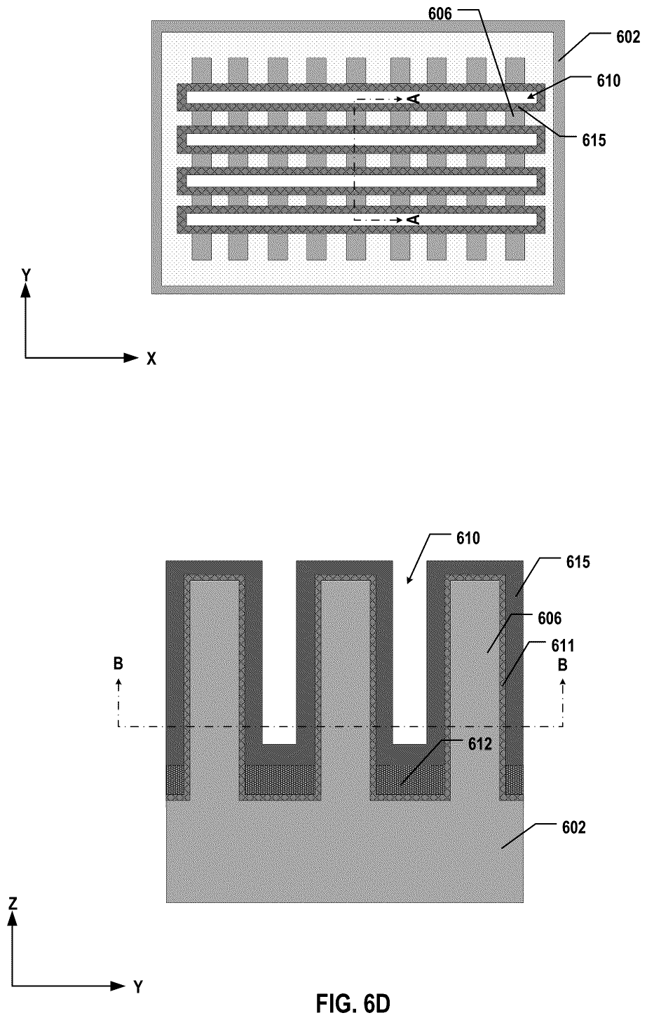

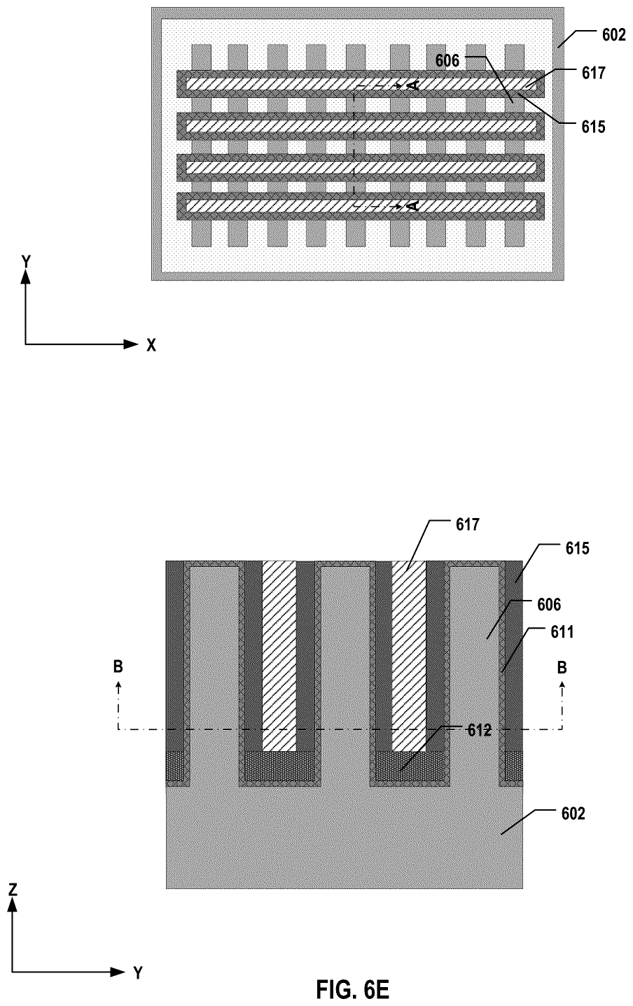

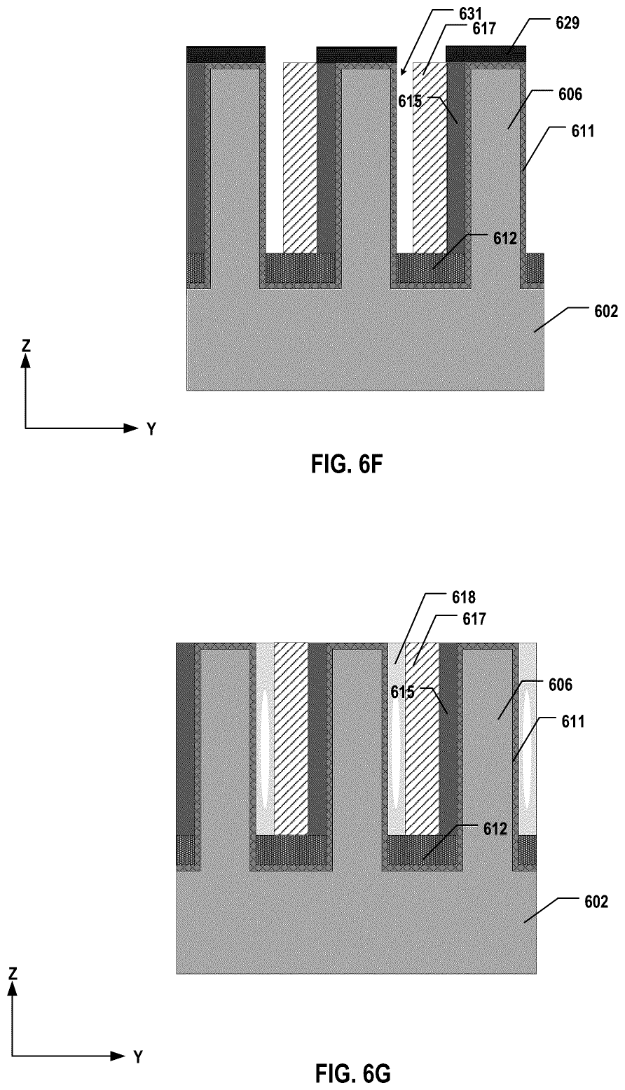

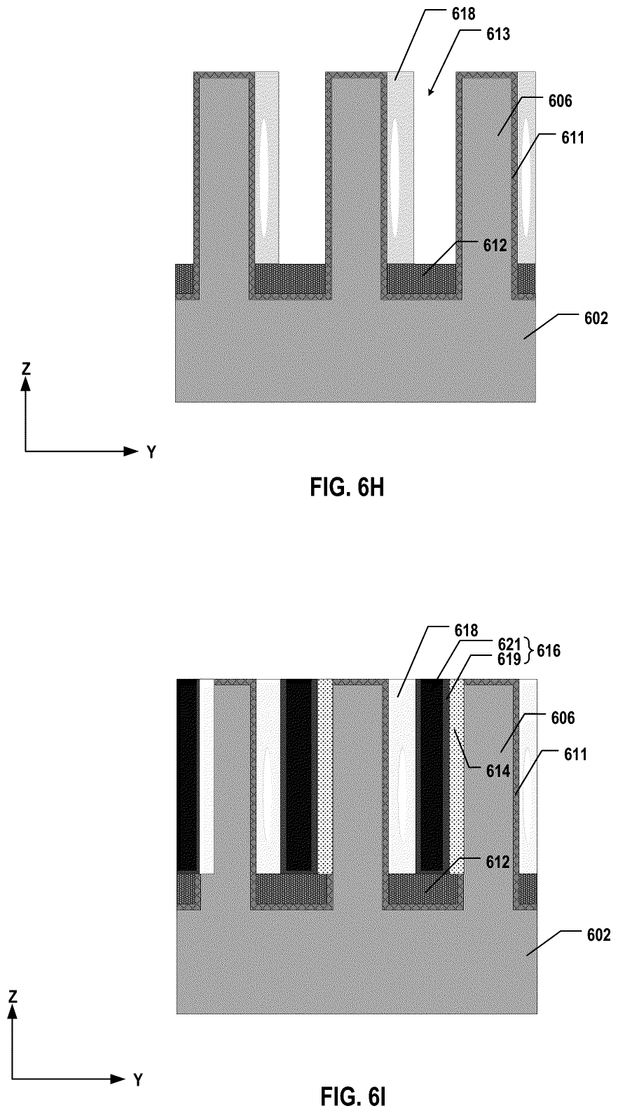

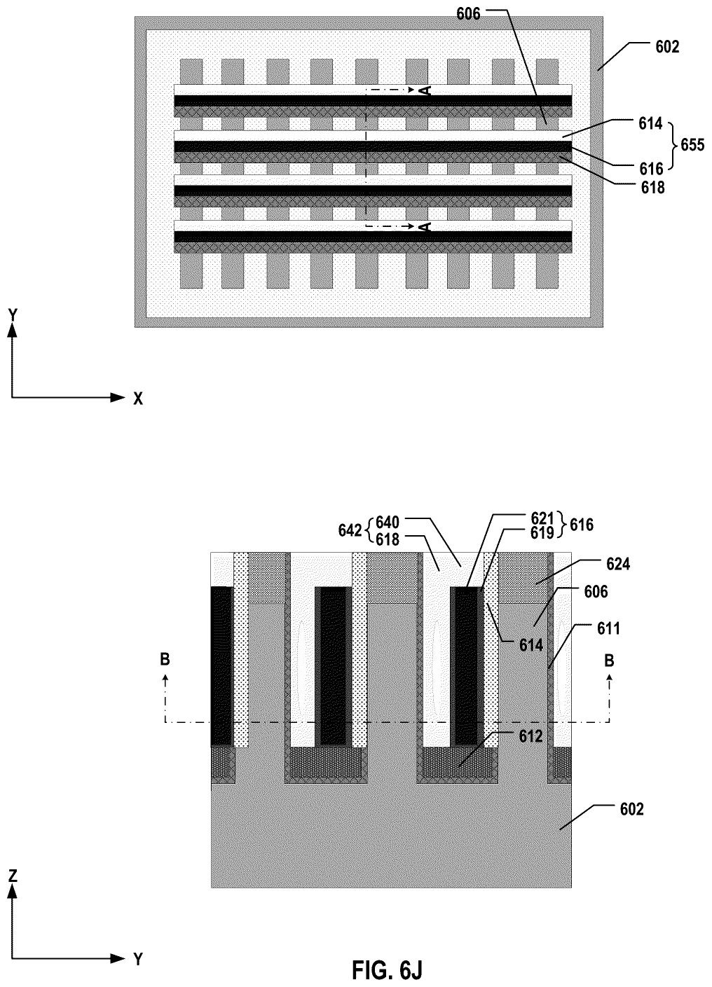

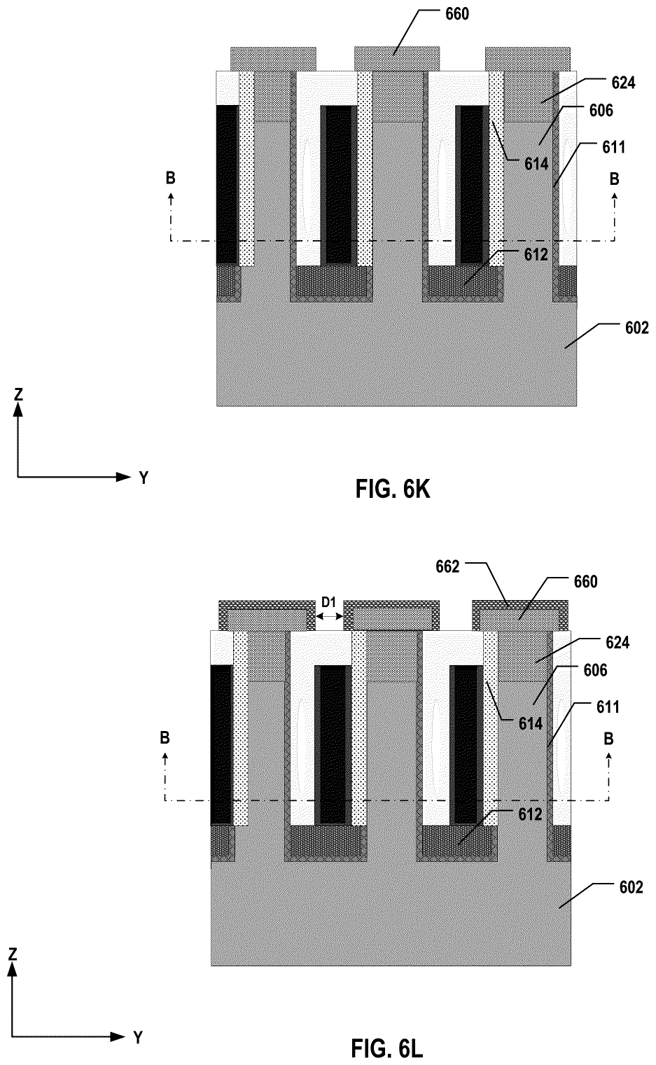

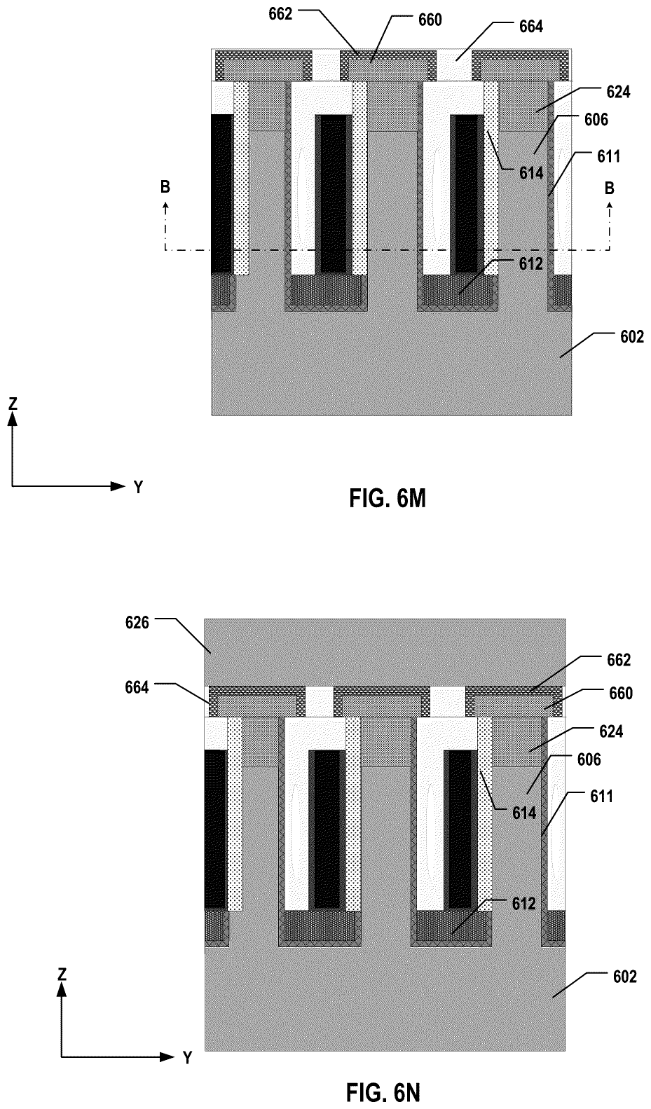

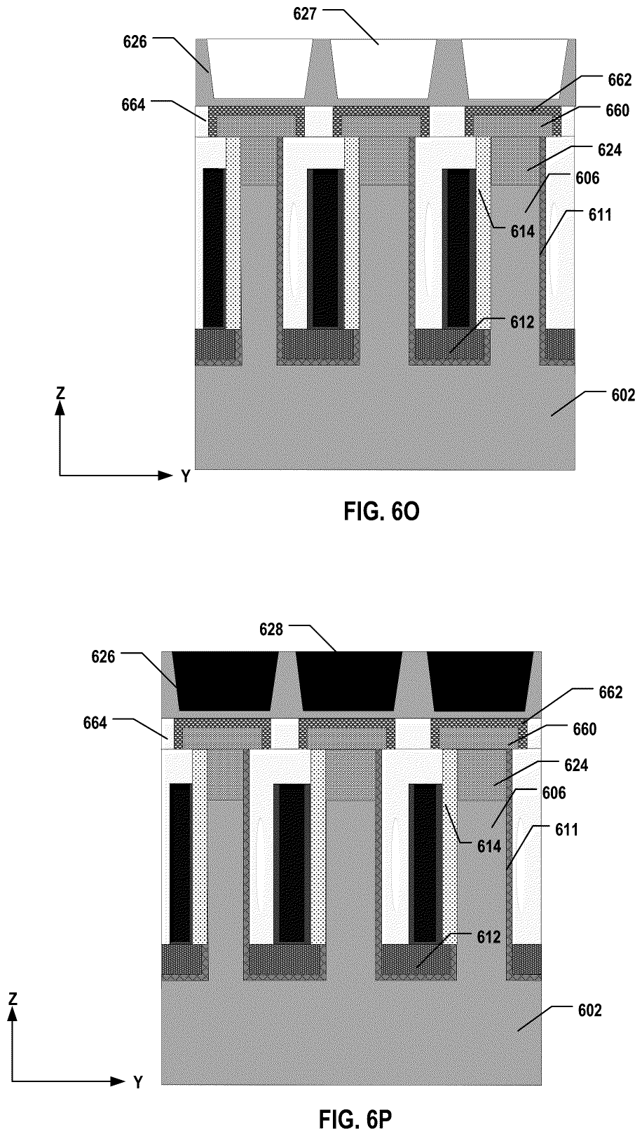

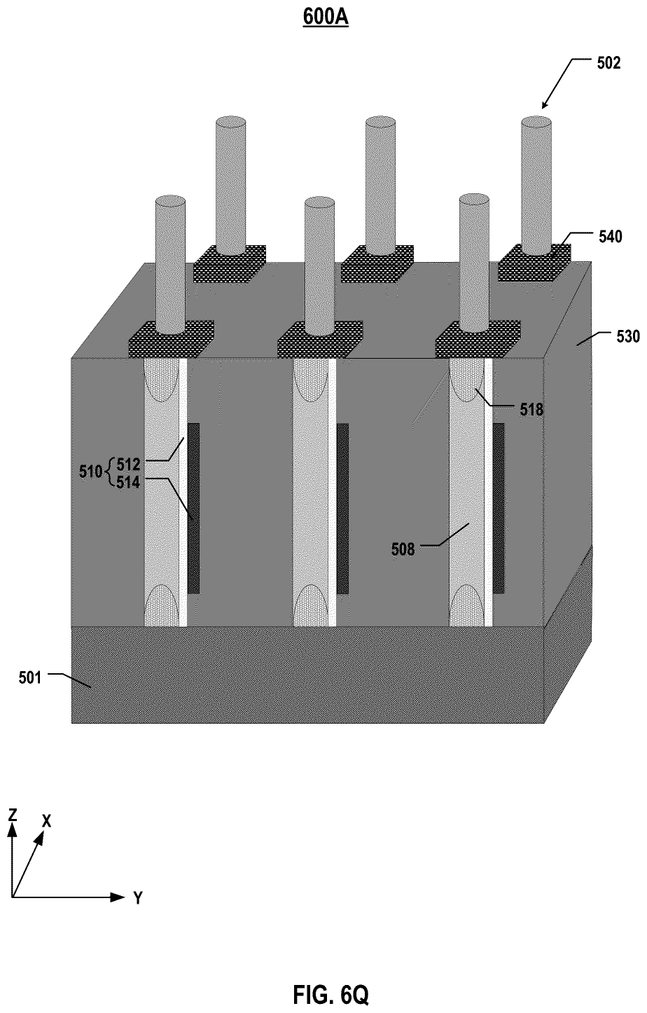

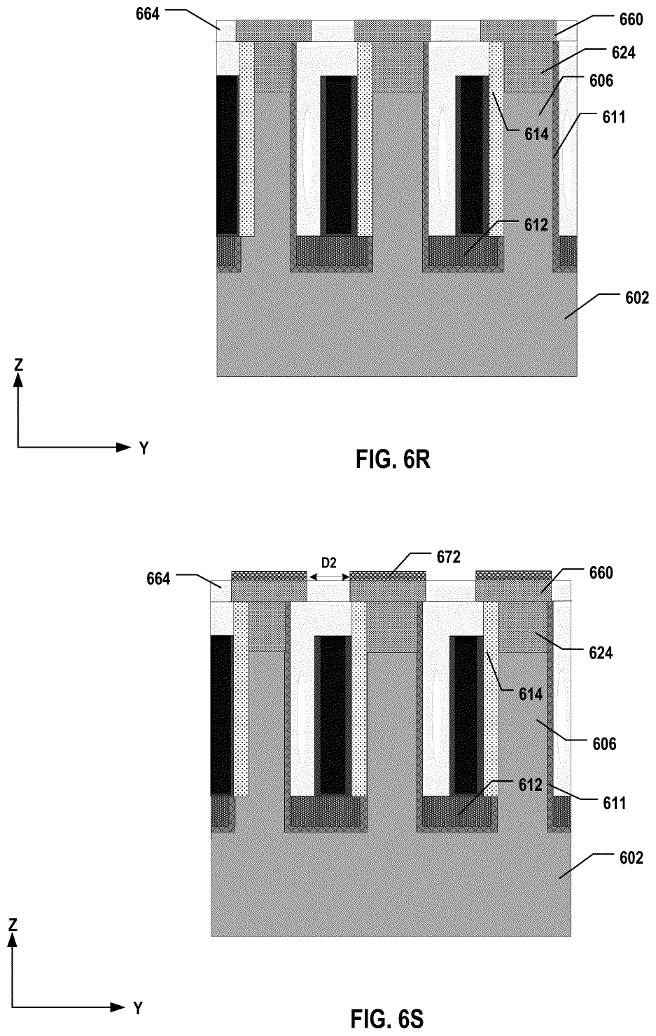

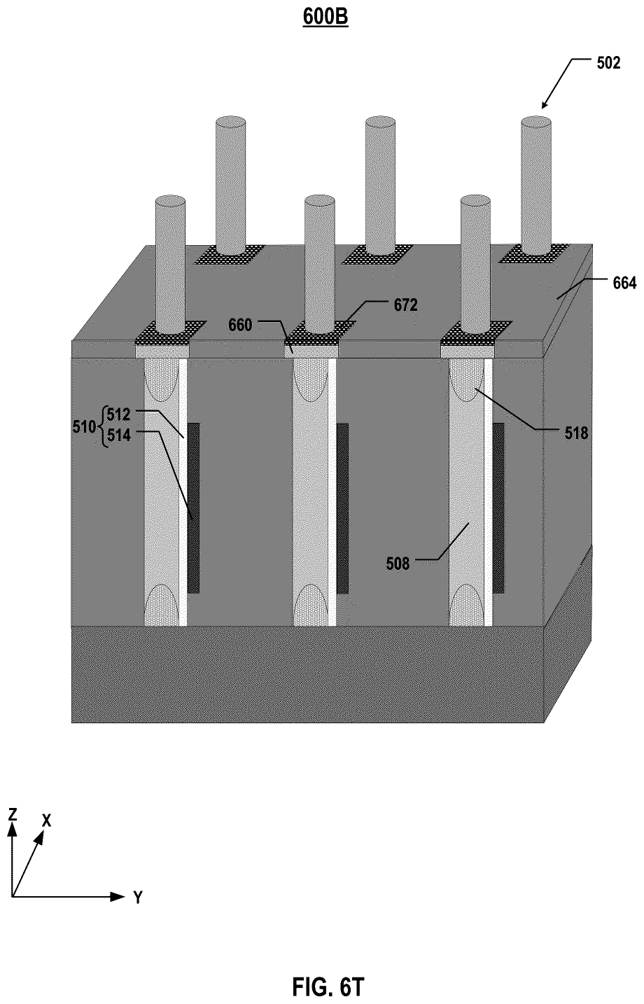

Referring to FIG. 6Q, in some implementation, a semiconductor structure 600A is provided to increase the linewidth of silicide in processes with a relatively small feature size. Semiconductor structure 600A includes a plurality of vertical transistors 502 and a memory controller (not shown) coupled to semiconductor structure 600A and configured to control the semiconductor structure 600A. Each vertical transistor 502 of at least part of the plurality of vertical transistors includes a semiconductor body 508 extending in a first direction (i.e., z-direction in FIG. 6Q) from a substrate 501. Semiconductor body 508 includes a source/drain 518 at one end of semiconductor body. A gate structure 510 is coupled to at least one side of semiconductor body 508. A gate structure 510 includes a gate dielectric 512 and a gate electrode 514. A source/drain epitaxial structure is formed on a source/drain 518 far away from substrate 501. A projection of the source/drain epitaxial structure on substrate 501 is larger than a projection of source/drain 518, as shown in FIG. 6Q. A silicide 540 is formed on a top surface and at least part of the side surfaces of source/drain epitaxial structure. In FIG. 6, a silicide 540 covers all the surface exposed from an isolation layer 530 to increase the area of silicide 540 as much as possible, an area of silicide 540 is larger than an area of a first surface of source/drain 518. FIG. 6T illustrates another implementation in which the side surfaces of source/drain epitaxial structure are covered by a second isolation layer 664, and a silicide 672 is formed on the top surface of the source/drain epitaxial structure. This implementation is applied when the distance between two adjacent transistors is small, and silicide formed on the side surfaces may lead to a short circuit.

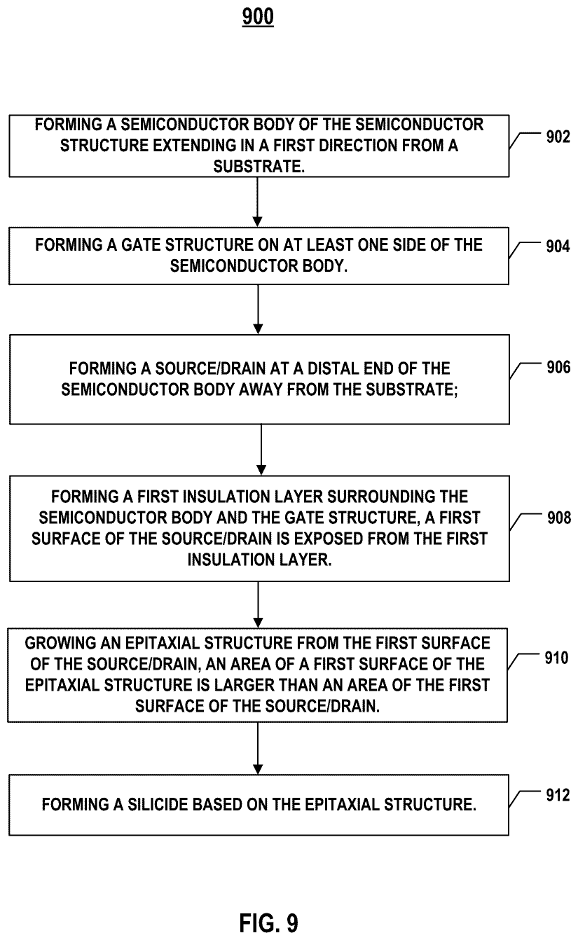

FIGS. 6A-6R illustrate a fabrication process for forming a semiconductor device including vertical transistors having a silicide with an increased linewidth, according to some aspects of the present disclosure. FIG. 9 illustrates a flowchart of a method 900 for forming the semiconductor device including vertical transistors having a silicide with an increased linewidth, according to some aspects of the present disclosure. It is understood that the operations shown in method 900 are not exhaustive and that other operations can be performed as well before, after, or between any of the illustrated operations. Further, some of the operations may be performed simultaneously, or in a different order than shown in FIG. 9.

Referring to FIG. 9, method 900 starts at operation 902, in which a semiconductor body of a vertical transistor extending in a first direction on a substrate is formed. The substrate can be a silicon substrate.

As illustrated in FIG. 6A, a plurality of parallel semiconductor walls 605 are formed in the y-direction (the bit line direction). To form semiconductor walls 605, a plurality of parallel trenches are formed in a silicon substrate 602 in the y-direction. In some implementations, a lithography process is performed to pattern the trenches and semiconductor walls 605 using an etch mask 604 (e.g., a photoresist mask and/or a hard mask), for example, based on the design of bit lines, and one or more dry etching and/or wet etching processes, such as reactive ion etching (RIE), are performed to etch the trenches in silicon substrate 602. Thus, semiconductor wall 605 extending in the vertical direction on silicon substrate 602 can be formed. Since semiconductor walls 605 are formed by etching silicon substrate 602, semiconductor walls 605 can have the same material as silicon substrate 602, such as single crystalline silicon. FIG. 6A illustrates both the side view (in the bottom portion of FIG. 6A) of a cross-section along the x-direction (the word line direction, e.g., in the AA plane) and the plan view (in the top portion of FIG. 6A) of a cross-section in the x-y plane (e.g., in the BB plane through semiconductor walls 605).

As illustrated in FIG. 6A, trench isolations 608 are formed in the trenches. In some implementations, a dielectric, such as silicon oxide and/or silicon nitride, is deposited to fully fill the trenches using one or more thin film deposition processes including, but not limited to, chemical vapor deposition (CVD), physical vapor deposition (PVD), atomic layer deposition (ALD), or any combination thereof. In some implementations, a planarization process, such as chemical mechanical polishing (CMP), is performed to remove excess dielectric deposited beyond the top surface of etch mask 604. As a result, parallel semiconductor walls 605 can be separated by trench isolations 608. It is understood that in some examples, before depositing trench isolations 608, a liner layer (e.g., a native oxide layer, not shown) may be formed on the sidewalls of semiconductor walls 605 to cure the defects on the sidewalls of semiconductor walls 605 caused by the etching process.

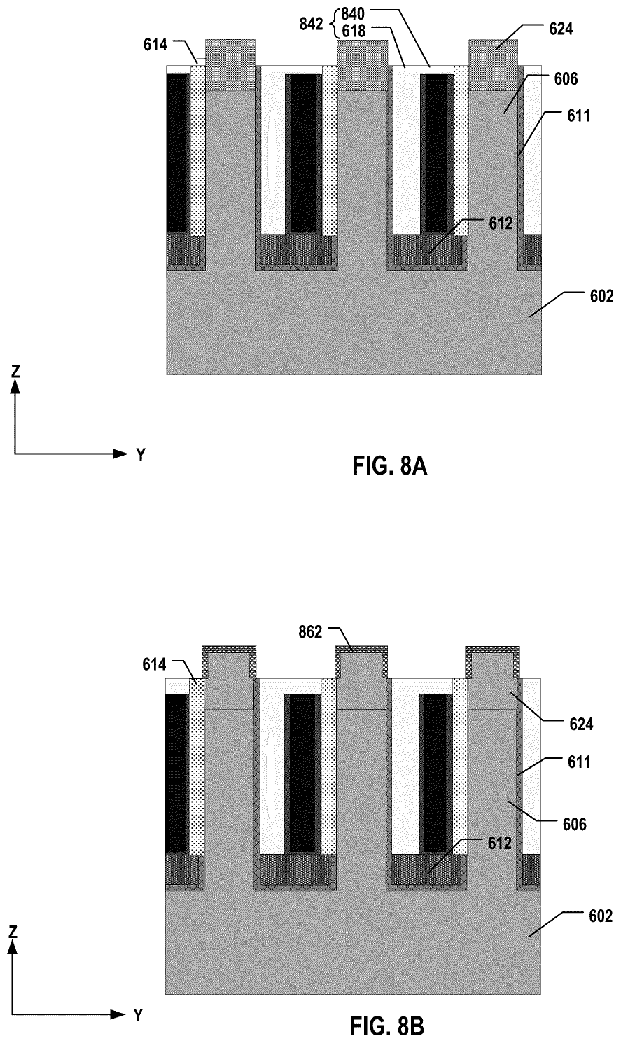

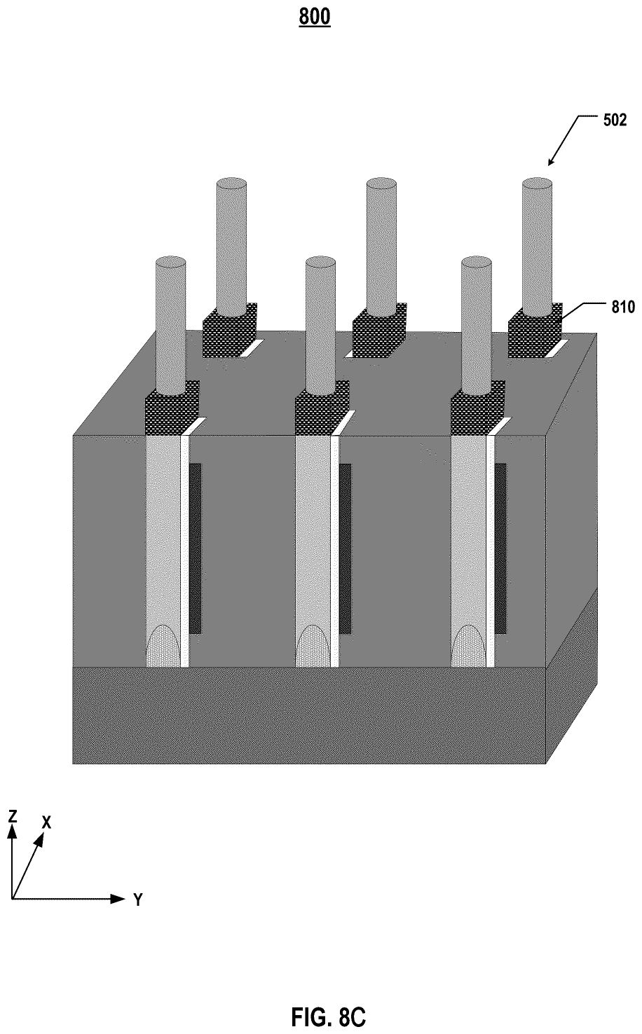

As illustrated in FIG. 6B, a plurality of parallel trenches 610 are formed each extending in the x-direction (the word line direction) to form an array of semiconductor bodies 606 each extending in the vertical direction on silicon substrate 602. In some implementations, a lithography process is performed to pattern trenches 610 to be perpendicular to trench isolations 608 using an etch mask (e.g., a photoresist mask and/or a hard mask), for example, based on the design of word lines, and one or more dry etching and/or wet etching processes, such as RIE, are performed on silicon substrate 602 and trench isolation 608 to etch trenches 610 in silicon substrate 602. As a result, semiconductor walls 605 (shown in FIG. 8A) can be cut by trenches 610 to form an array of semiconductor bodies 606 each extending vertically on silicon substrate 602. Since semiconductor bodies 606 are formed by etching silicon substrate 602, semiconductor bodies 606 can have the same material as silicon substrate 602, such as single crystalline silicon. FIG. 6B illustrates both the side view (in the bottom portion of FIG. 6B) of a cross-section along the y-direction (the bit line direction, e.g., in the AA plane through semiconductor bodies 606) and the plan view (in the top portion of FIG. 6B) of a cross-section in the x-y plane (e.g., in the BB plane through semiconductor bodies 606).

As illustrated in FIG. 6C, a liner layer 611 is formed on the top surface and the sidewalls of semiconductor body 606. Liner layer 611 can be a native oxide layer of semiconductor body 606 having single crystalline silicon, for example, grown using thermal oxidation (e.g., in situ steam generation (ISSG) oxidation), which can cure the defects on the surfaces of semiconductor body 606 caused by the etching processes. A pad layer 612 can be formed on top of silicon substrate 602, at the bottom of trench 610, for example, by depositing a dielectric, such as silicon nitride and/or high-k dielectrics (e.g., Al₂O₃), to partially fill trench 610, using one or more thin film deposition processes including, but not limited to, CVD, PVD, ALD, or any combination thereof. In some implementations, pad layer 612 has silicon nitride. The deposition conditions, such as deposition rate and/or time, can be controlled to control the thickness of pad layer 612 and avoid fully filling trench 610. As a result, the bottom surface of trench 610 can be elevated to be above the bottom surface of semiconductor body 606. As described below in detail, since pad layer 612 is used as the stop layer in removing silicon substrate 602 and to form the step between semiconductor body 606 and the gate electrode later, the thickness (the dimension in the vertical direction) of pad layer 612 can be determined based on the step and/or the substrate removing process.

FIG. 6C illustrates both the side view (in the bottom portion of FIG. 6C) of a cross-section along the y-direction (the bit line direction, e.g., in the AA plane through semiconductor bodies 606) and the plan view (in the top portion of FIG. 6C) of a cross-section in the x-y plane (e.g., in the BB plane through semiconductor bodies 606 and pad layer 612). As shown in the side view, the two opposite sides of semiconductor body 606 in the y-direction are partially exposed by trenches 610 (not considering liner layer 611); as shown in the plan view, the other two opposite sides of semiconductor body 606 in the x-direction are in contact with trench isolations 608. In other words, semiconductor body 606 is surrounded by trenches 610 and trench isolations 608.

As illustrated in FIG. 6D, sacrificial layers 615 are formed on the sidewalls and the top surfaces of semiconductor body 606. For each semiconductor body 606, two sacrificial layers 615 can be formed on the two opposite sides of each semiconductor body 606 in the bit line direction (the y-direction), as shown in the plan view. As shown in the side view, sacrificial layers 615 can be a continuous layer in the bit line direction as sacrificial layers 615 can be deposited over the top surfaces of semiconductor bodies 606 and the bottom surfaces of trenches 610 as well. In some implementations, sacrificial layers 615 are formed by depositing one or more materials that are different from the materials of pad layers 612 and liner layers 611 over pad layers 612 and liner layers 611 using one or more thin film deposition processes including, but not limited to, CVD, PVD, ALD, or any combination thereof, to partially fill trenches 610. For example, a high-k dielectric, such as Al₂O₃, may be deposited to form sacrificial layers 615 over pad layers 612 having silicon nitride and liner layers 611 having silicon oxide. FIG. 6D illustrates both the side view (in the bottom portion of FIG. 6D) of a cross-section along the y-direction (the bit line direction, e.g., in the AA plane through semiconductor bodies 606) and the plan view (in the top portion of FIG. 6D) of a cross-section in the x-y plane (e.g., in the BB plane through semiconductor bodies 606 and sacrificial layers 615).

In some implementations, the first sacrificial layers formed on the first and second sides of the semiconductor body are separated from one another. As illustrated in FIG. 6E, parts of sacrificial layers 615 that are formed over the top surfaces of semiconductor bodies 606 and the bottom surfaces of trenches 610 are removed, leaving sacrificial layers 615 formed only on the sidewalls of semiconductor bodies 606 in the bit line direction. That is, parts of sacrificial layers 615 at the bottom surfaces of trenches 610 can be removed to separate the continuous layer into discrete pieces in the bit line direction. Thus, two sacrificial layers 615 on the two opposite sides of each semiconductor body 606 in the bit line direction can be separated from one another. In some implementations, parts of sacrificial layers 615 that are formed over the bottom surfaces of trenches 610 are removed by a dry etching process, such as RIE, and parts of sacrificial layers 615 that are formed over the top surfaces of semiconductor bodies 606 are removed by the same dry etching process and/or a planarization process, such as CMP.

As illustrated in FIG. 6E, sacrificial layers 617 are formed on the sidewalls of sacrificial layers 615 to fill trenches 610 (shown in FIG. 6D). Each sacrificial layer 617 can be a continuous layer in the word line direction and surrounded by sacrificial layer 615, as shown in the plan view. In some implementations, sacrificial layers 617 are formed by depositing one or more materials that are different from the materials of pad layers 612 and sacrificial layers 615 over pad layers 612 and sacrificial layers 615 using one or more thin film deposition processes including, but not limited to, CVD, PVD, ALD, or any combination thereof, to fully fill trenches 610. For example, polysilicon may be deposited to form sacrificial layers 617 over pad layers 612 having silicon nitride and sacrificial layers 615 having a high-k dielectric (e.g., Al₂O₃). Similar to sacrificial layers 615, any excess materials of sacrificial layers 617 over the top surfaces of semiconductor bodies 606 and sacrificial layers 615 can be removed by a dry etching process, such as RIE, and/or a planarization process, such as CMP, to separate sacrificial layers 617 into discrete pieces in the bit line direction. Thus, for each semiconductor body 606, a pair of sacrificial layers 615 and 617 are sequentially formed on one side in the bit line direction, and another pair of sacrificial layers 615 and 617 are sequentially formed on the opposite side in the bit line direction, according to some implementations. FIG. 6E illustrates both the side view (in the bottom portion of FIG. 6E) of a cross-section along the y-direction (the bit line direction, e.g., in the AA plane through semiconductor bodies 606) and the plan view (in the top portion of FIG. 6E) of a cross-section in the x-y plane (e.g., in the BB plane through semiconductor bodies 606 and sacrificial layers 615 and 617).

Then method 900 proceeds to method 904 to form a gate structure on at least one side of semiconductor bodies 606 according to a self-aligned gate process. The self-aligned gate process can be used to form both single-gate transistors and multi-gate transistors. There are various methods to form the gate structure of a vertical transistor. The self-aligned gate process described herein is for illustrative purposes only and should not be interpreted as a limitation of the present disclosure.

As illustrated in FIG. 6F, sacrificial layers 615 on one side of semiconductor bodies 606 in the bit line direction where the gate structures are not to be formed (shown in FIG. 6E) are removed to form trenches 631, exposing the opposite side of semiconductor bodies 606 where the gate structures are not to be formed. To remove sacrificial layer 615, a lithography process, such as self-aligned double patterning (SADP) or self-aligned quadruple patterning (SAQP), can be performed to pattern trenches 631 using an etch mask 629 (e.g., a photoresist mask and/or a hard mask), which exposes sacrificial layers 615 on one side of semiconductor bodies 606 in the bit line direction where the gate structures are not to be formed, but covers and protects sacrificial layers 615 on the other side of semiconductor bodies 606 in the bit line direction where the gate structures are to be formed, as shown in FIG. 6F. Then, one or more selective etching processes, such as wet etching, can be performed through etch mask 629 to etch away only sacrificial layers 615 on one side of semiconductor bodies 606 in the bit line direction where the gate structures are not to be formed, leaving sacrificial layers 615 on the opposite side of semiconductor bodies 606 intact. The etchant can have a relatively high selectivity (e.g., greater than 5 times) of sacrificial layers 615 with respect to sacrificial layers 617 and liner layers 611, thereby leaving sacrificial layers 617 and liner layers 611 intact as well, even without the protection of etch mask. For example, etchants having phosphoric acid (H₃PO₄) may be used to selectively remove sacrificial layers 615 having Al₂O₃, without removing sacrificial layers 617 having polysilicon and liner layers 611 having silicon oxide.

As illustrated in FIG. 6G, dielectric isolation layers 618 are formed on the exposed side of semiconductor bodies 606 where sacrificial layers 615 are selectively removed. To form dielectric isolation layers 618, dielectric material(s), such as silicon oxide, is deposited using one or more thin film deposition processes including, but not limited to, CVD, PVD, ALD, or any combination thereof, to fill trenches 631 (shown in FIG. 6F). Depending on the lateral dimensions of trenches 631, trenches 631 may not be fully filled with the deposited dielectric material(s) (e.g., silicon oxide) when forming dielectric isolation layers 618 and thus, become air gaps therein according to the self-aligned gate process for forming “thick gate,” as shown in FIG. 6G. It is understood that in some examples, when the lateral dimensions of trenches 631 are sufficiently large, dielectric material(s) may fully fill trenches 631 during the formation of dielectric isolation layers 618, thereby eliminating the air gaps.

As illustrated in FIG. 6H, sacrificial layers 617 and remaining sacrificial layers 615 are selectively removed to form trenches 613, exposing the side of semiconductor bodies 606 where the gate structures are to be formed. Selective etching processes, such as wet etching, can be sequentially performed to etch away sacrificial layers 617 and the remaining sacrificial layers 615. The first etchant can have a relatively high selectivity (e.g., greater than 5 times) of sacrificial layers 617 with respect to dielectric isolation layers 618 and liner layers 611, and the second etchant can have a relatively high selectivity (e.g., greater than 5 times) of sacrificial layers 615 with respect to dielectric isolation layers 618 and liner layers 611, thereby leaving dielectric isolation layers 618 and liner layers 611 intact. For example, the first etchant having potassium hydroxide (KOH) may be used to selectively remove sacrificial layers 617 having polysilicon, and the second etchant having phosphoric acid (H₃PO₄) may be used to selectively remove sacrificial layers 615 having Al₂O₃, without removing dielectric isolation layers 618 and liner layers 611 both having silicon oxide. As shown in FIG. 6H, pad layers 612 can remain after removing sacrificial layers 615 and 617.

As illustrated in FIG. 6I, gate dielectrics 614 are formed on the exposed side of semiconductor bodies 606 in trenches 613 (shown in FIG. 6H). Gate dielectrics 614 are not formed on the opposite side of semiconductor bodies 606 in the bit line direction where dielectric isolation layers 618 are formed, according to some implementations. In some implementations, gate dielectrics 614 are formed by depositing a layer of dielectric, such as silicon oxide, over the exposed sidewall of semiconductor bodies 606 using one or more thin film deposition processes including, but not limited to, CVD, PVD, ALD, or any combination thereof, without fully filling trenches 613. It is understood that in some examples, gate dielectrics 614 may not be parts of a continuous dielectric layer. For example, a thermal oxidation process, such as ISSG oxidation, is performed to further grow native oxide (e.g., silicon oxide) on semiconductor bodies 606 (e.g., single crystalline silicon) from liner layer 611 to become gate dielectric 614. It is also understood that since gate dielectrics 614 and liner layers 611 may have the same materials, such as silicon oxide, the interface and boundary between gate dielectrics 614 and liner layers 611 may become indistinguishable. Thus, for ease of description, liner layers 611 that are in contact with gate dielectrics 614 may be illustrated as part of gate dielectrics 614 in the present disclosure, for example, as shown in FIG. 6I.

As illustrated in FIG. 6I, gate electrodes 616 are formed on the side of gate dielectrics 614 in trenches 613 (shown in FIG. 6H). Gate electrode 616 can be formed between gate dielectric 614 and dielectric isolation layer 618 in the bit line direction to fill trench 613. In some implementations, gate electrode 616 includes a gate conductor 621 and a barrier layer 619 surrounding gate conductor 621. In some implementations, gate electrodes 616 are formed by depositing one or more layers of conductive layers, such as metals or metal compounds, over the exposed sidewall of gate dielectrics 614 using one or more thin film deposition processes including, but not limited to, CVD, PVD, ALD, or any combination thereof, fully filling trenches 613. For example, a layer of TiN and a layer of W may be sequentially deposited into trench 613 to form barrier layer 619 having TiN and gate conductor 621 having W, respectively. That is, the self-aligned gate process disclosed herein can allow the later deposited gate conductor 621 to be surrounded by the first deposited barrier layer 619 when filling trench 613.

After the gate structure is formed, method 900 proceeds to operations 906 and 908, forming a source/drain at a distal end of semiconductor bodies 606 away from silicon substrate 602, and forming a first isolation layer surrounding semiconductor bodies 606 and the gate structure. A first surface and at least part of a second surface of the source/drain are exposed from the first isolation layer. The second surface is vertical to the first surface.

As illustrated in FIG. 6J, a top portion of gate electrode 616 is replaced with a dielectric plug 640, making the top end of gate electrode 616 below the top end of semiconductor body 606. To form dielectric plug 640, gate electrode 616 can be etched back (recessed) from the top by wet etching and/or drying etching, such that the upper end of gate electrode 616 becomes below the top surface of semiconductor body 606, and the resulting recess can be filled with dielectric plug 640 by depositing dielectrics, such as silicon oxide, using one or more thin film deposition processes including, but not limited to, CVD, PVD, ALD, or any combination thereof. Dielectric isolation layer 618 and dielectric plug 640 form a first isolation layer 642 surrounding semiconductor bodies 606. It is understood that since dielectric isolation layer 618 and dielectric plug 640 may have the same materials, such as silicon oxide, the interface and boundary between dielectric isolation layer 618 and dielectric plug 640 may become indistinguishable. The remainder of gate electrode 616 (referring to hereafter as “gate electrode 616” for ease of description) and gate dielectric 614 in contact with gate electrode 616 become a gate structure 655 coupled to one side of semiconductor body 606 in the bit line direction, according to some implementations, as shown in FIG. 6J. FIG. 6J illustrates both the side view (in the bottom portion of FIG. 6J) of a cross-section along the y-direction (the bit line direction, e.g., in the AA plane through semiconductor bodies 606) and the plan view (in the top portion of FIG. 6J) of a cross-section in the x-y plane (e.g., in the BB plane through semiconductor bodies 606, gate electrodes 616, and gate dielectrics 614).

As illustrated in FIG. 6J, the exposed top end (e.g., the end away from silicon substrate 602 in the vertical direction) of semiconductor body 606 is doped to form a drain or a source 624 (referrer to hereinafter “source/drain 624”) of the vertical transistor. For example, source/drain 624 may be the source terminal of the vertical transistor. In some implementations, an implantation process and/or thermal diffusion process are performed to dope P-type dopants or N-type dopants to exposed upper ends of semiconductor bodies 606 to form sources/drains 624.

After source/drain 624 and first isolation layer 642 are formed, method 900 proceeds to operation 910 to grow an epitaxial structure from the first surface of source/drain 624. An area of a first surface of the epitaxial structure is larger than the area of the first surface of the source/drain 624.

As illustrated in FIG. 6K, an epitaxial structure 660 is formed on the top surface of source/drain 624 through CVD, PVD, ALD, or any combination thereof. Crystal plane orientation has a significant impact on the shape and size of epitaxial structure 660 formed by epitaxy. In a CVD process, for example, when the crystal plane orientations used for epitaxy growth are (111), (110), and (100), the resulting shapes of the epitaxially grown epitaxial structures 660 are hexagonal, trapezoidal, and rectangular, respectively. By selecting the crystal plane orientation and controlling the parameters of CVD, it is possible to generate epitaxial structures 660 with a desired shape and size. For example, in FIG. 6K, a rectangular epitaxial structure is designed to form a cuboid epitaxial structure. It is understood that epitaxial structures 660 can be any suitable shape and size as long as a projection of epitaxial structures 660 on silicon substrate 602 is larger than a projection of source/drain 624 on silicon substrate 602.

After epitaxial structures 660 are formed, method 900 proceeds to operation 912 to form a silicide based on epitaxial structure 660.

As illustrated in FIG. 6L, a silicide 662 is formed to cover epitaxial structures 660. To form silicide 662, and a first step is to deposit a layer of metal (such as Ti, Co, and NiPt) on epitaxial structures 660 using PVD. Then, two rapid thermal annealing (RTA) processes and one selective wet etching treatment are performed to form silicide 662 on the exposed surface of epitaxial structures 660. Metal silicides, including TiSi₂, CoSi₂, and NiPtSi, are formed. Metals such as Ti, Co, or NiPt will not react with the dielectric material, i.e., first isolation layer 642, to form metal silicide. They will only react with the epitaxial structures 660 in direct contact to form metal silicide. Silicide 662 can reduce the square resistance and contact resistance of epitaxial structures 660.

In this embodiment, two RTA processes are required to form silicide 662, taking the titanium disilicide process as an example. First, a layer of Ti film is deposited, followed by a layer of TiN film covering the Ti film. The purpose of depositing the TiN film is to prevent Ti from flowing during rapid thermal annealing. The temperature of the first RTA is relatively low, only 450˜650° C., at which Ti reacts with the silicon in epitaxial structures 660 to form a high-resistance metal silicide Ti₂Si, which has a body-centered tetragonal crystal structure (C49 phase). Ti will not react with silicon dioxide to generate metal silicide, so selective wet etching can be used to remove the surface TiN film and the Ti film that does not react with silicon dioxide. The second RTA has a high temperature, at least 750° C., and some process platforms require as high as 950° C. The second RTA can convert the high-resistance metal silicide Ti₂Si in the C49 phase into the low-resistance metal silicide TiSi₂ in the face-centered orthorhombic crystal structure (C54 phase). TiSi₂ has good thermodynamic properties and is very stable. If only one RTA is used to generate low-resistance metal silicide TiSi₂, the process temperature of this step will be very high. In a high-temperature environment, silicon can diffuse along the grain boundaries of TiSi₂, causing excessive growth of TiSi₂ on the silicon dioxide boundary, which cannot be removed by wet etching, leading to a short circuit.

As illustrated in FIG. 6M, after silicide 662 is formed, a second isolation layer 664 is formed to surround silicide 662, and the top surface of silicide 662 is exposed from second isolation layer 664 so that second isolation layer 664 aligns with silicide 662. As illustrated in FIG. 6N, a landing layer 626 is formed above second isolation layer 664 and silicide 662. Landing layer 626 is a dielectric layer configured to separate silicide 662 from a metal layer formed above the vertical transistors. Landing layer 626 can be formed by depositing silicon oxide and/or silicon nitride on second isolation layer 664 and silicide 662 through PVD. The deposited dielectric material is then planarized to remove any excess material and create a smooth, flat surface to form the metal layer, such as CMP.

As illustrated in FIG. 6O, through holes 627 are formed on landing layer 626 to expose silicide 662 using a patterning process (e.g., photolithography and dry/wet etch of dielectric materials in landing layer 626), so that source/drain 624 can be connected to the metal layer through contact formed in through holes 627. A minimal area of a cross-section of through holes 627 is large than or equal to an area of the top surface of silicide 662 to decrease the contact resistance. In the present implementation, the area of the top surface of silicide 662 is improved greatly by the formation of epitaxial structure 660. For example, in the present implementation, referring to FIG. 6O, a minimal area of a cross-section of through holes 627 is more than two times of the area of the top surface of source/drain 624. An aspect ratio of a through hole is the ratio of its depth to its width. In the present implementation, the aspect ratio of through holes 627 is significantly reduced due to the increase of the width of through holes 627. This can make it easier to control the etch process and to remove residual material from the bottom of through holes 627. In addition, as an etching window area of the etching process increases, the difficulty of the process for etching through holes 627 decreases, which can effectively avoid open circuits caused by incomplete etching and damages to the source/drain 624 caused by over-etching.

After through holes 627 are formed, a metal contact 628 in touch with silicide 662 is formed in through holes 627 to connect silicide 662 to metal layer or source/drain contact for further connection, as illustrated in FIG. 6O. Metal contact 628 can be tungsten (W), copper (Cu), aluminum (Al), etc.), and metal compounds (e.g., titanium nitride (TiN), or tantalum nitride (TaN), etc.). Metal contact 628 can be formed by sputtering, evaporation, or electroplating. The increased aspect ratio of through holes 627 also reduces the difficulty of forming metal contact 628.

Another implementation of the present disclosure is illustrated in FIGS. 6R-6T. The present implementation differs from the above-described implementation in the order of forming the second isolation layer 664 and a silicide 672. Referring to FIGS. 6R and 6T, second isolation layer 664 forms before silicide 672 to surround epitaxial structure 660, so that all the side surfaces of epitaxial structure 660 are covered by second isolation layer 664 and only the top surface of epitaxial structure 660 is exposed outside. Therefore, silicide 672 can only be formed on the top surface of epitaxial structure 660, and a distance D2 between silicide 672 of two adjacent transistors in the present implementation is larger than a distance D2 between silicide 662 of two adjacent transistors in the above-described implementation, as shown in FIG. 6L and FIG. 6S. In this way, a short circuit caused by the possible contact of silicide between two adjacent transistors is avoided. FIG. 6T illustrates a perspective view of a semiconductor structure 600B of the present implementation according to FIG. 6L and FIG. 6S, it is clear that silicide 672 is only formed on the top surface of epitaxial structure 660 and the side surfaces of epitaxial structure 660 are surrounded by second isolation layer 664.

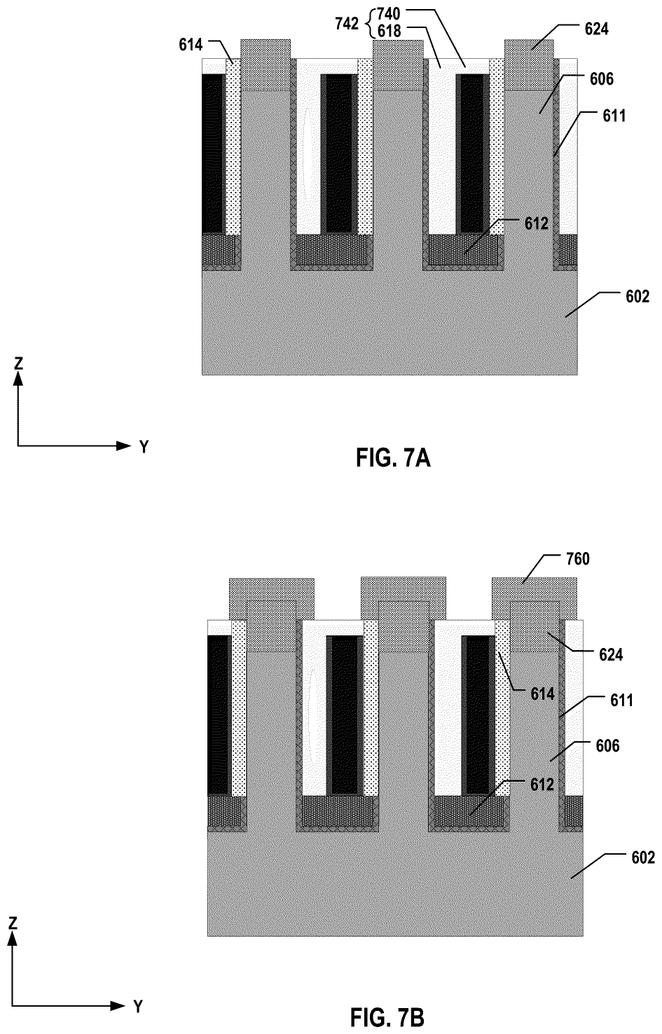

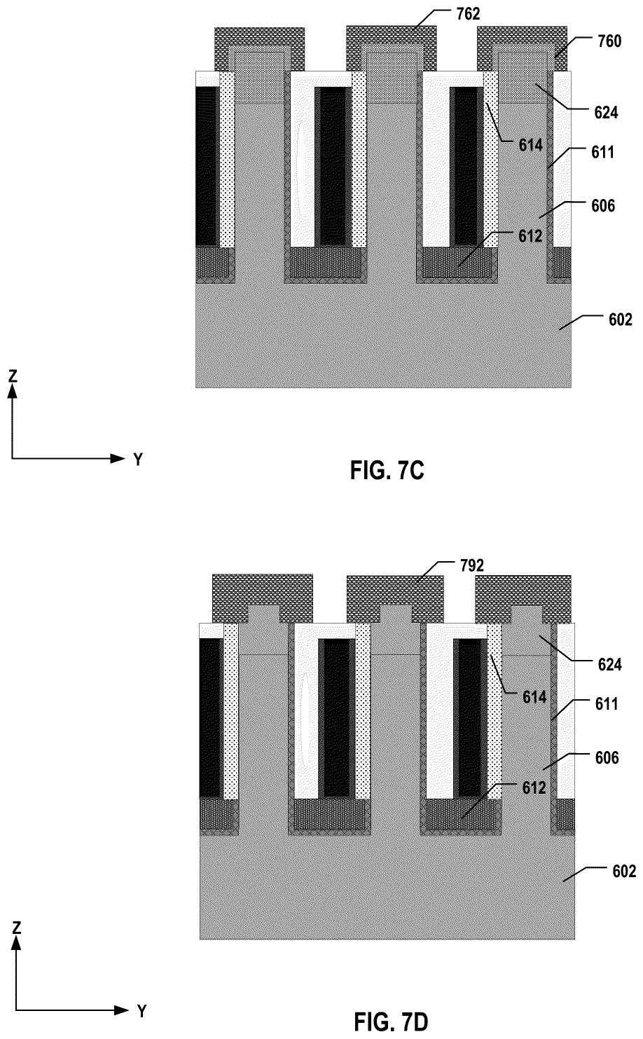

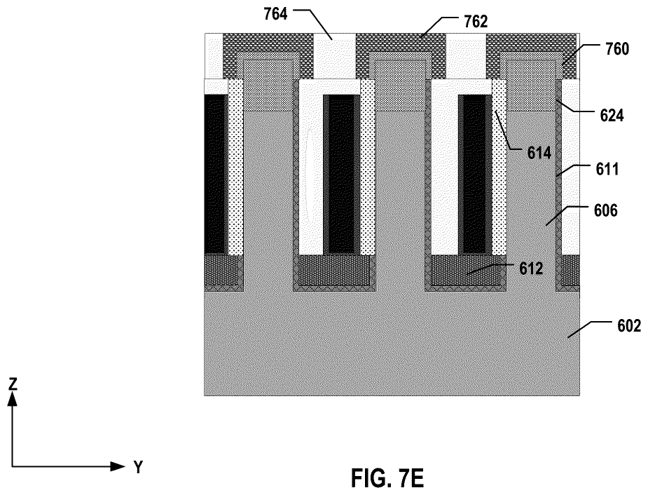

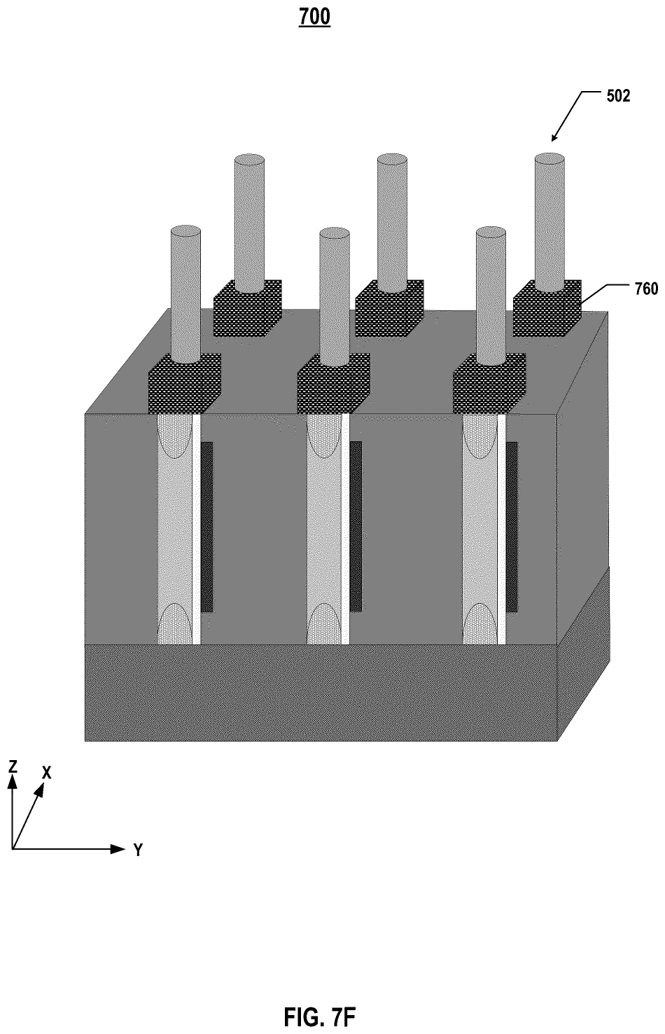

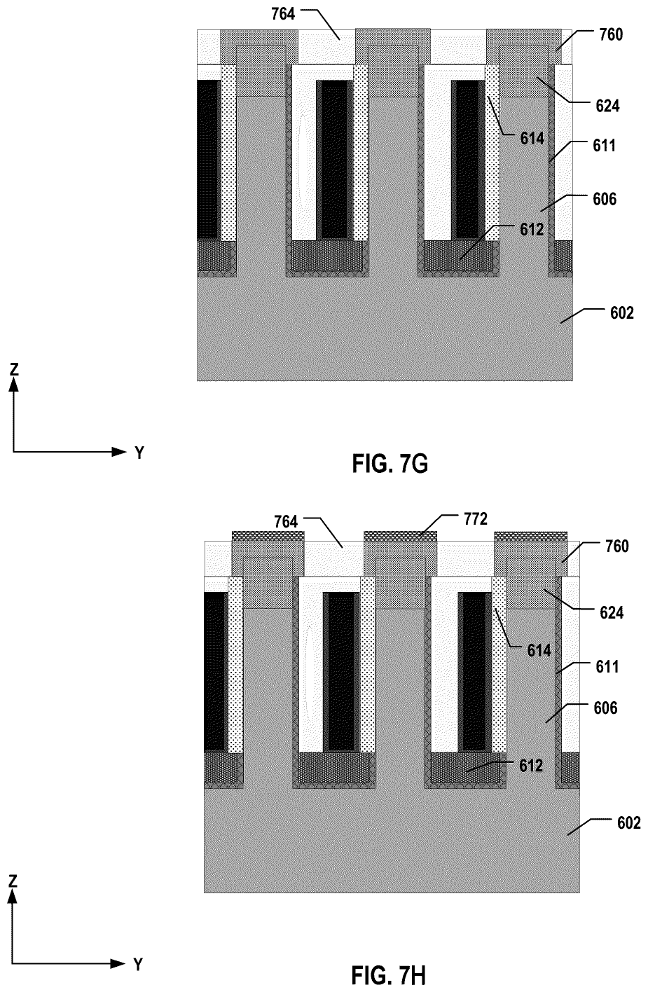

Referring to FIG. 7F and FIG. 8C, a semiconductor structure 700 and a semiconductor structure 800 are provided to increase the linewidths of silicide in processes with a relatively small feature size according to another implementation of the present disclosure. Semiconductor structure 700 and 800 differs from semiconductor structure 600A in the formation and structure of silicide in each vertical transistor 502. To form silicide 662 or 672 in semiconductor structure 600A, an epitaxial structure is formed based on and only based on the top surface of source/drain 624 because the side surfaces of source/drain 624 are covered by first isolation layer 642 and cannot be used for epitaxial growth. While to form silicide in semiconductor structure 700 and 800, first isolation layer 642 is etched to expose at least part side surfaces of source/drain 624. In semiconductor structure 700, an epitaxial structure is formed based on the top surface and at least part of the side surfaces of source/drain 624 to gain an epitaxial structure with a larger volume, so that the linewidth of silicide 762 can be increased as much as possible. In semiconductor structure 800, the epitaxial structure is eliminated, and silicide 810 is formed directly, without forming an epitaxial structure, on the top surface and at least part of the side surfaces of source/drain 624 to simplify the manufacturing process and reduce costs while increasing the linewidth of silicide.

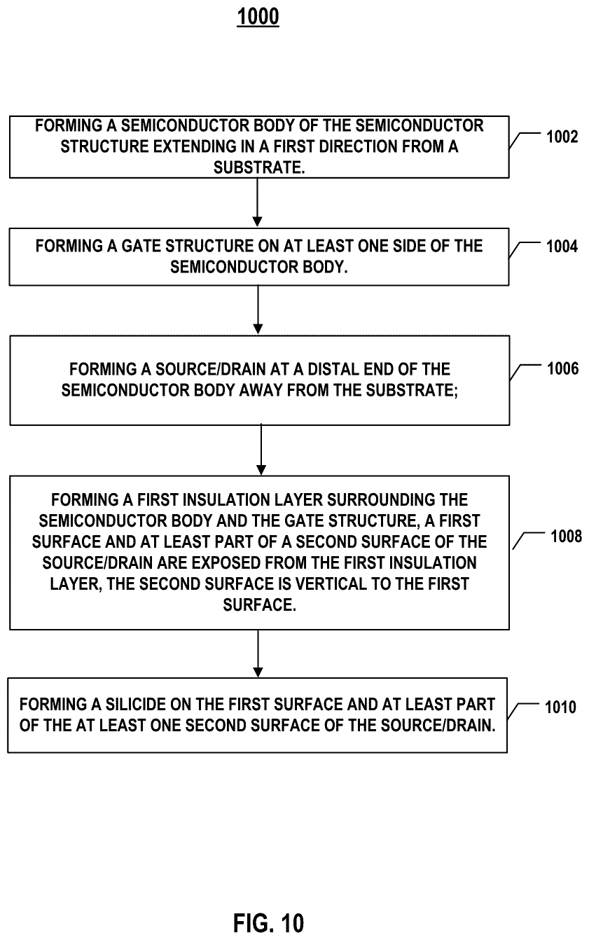

FIGS. 7A-7F illustrate differences of structure and fabrication process between semiconductor structures 700 and 600A. FIGS. 8A-8C illustrate differences of structure and fabrication process between semiconductor structures 800 and 600A. FIG. 10 illustrates a flowchart of a method 1000 for forming the semiconductor device including vertical transistors having a silicide with an increased linewidth. It is understood that the operations shown in method 1000 are not exhaustive and that other operations can be performed as well before, after, or between any of the illustrated operations. Further, some of the operations may be performed simultaneously, or in a different order than shown in FIG. 10.

Referring to FIG. 10, method 1000 starts at operations 1002 to 1006, in which a semiconductor body of a vertical transistor extending in a first direction on a substrate is formed. Then a gated structure is formed on at least one side of the semiconductor body, and a source/drain is formed at a distal end of the semiconductor body away from the substrate. The structure and manufacturing process in operations 1002 to 1006 may be the same as method 900 with respect to FIGS. 6A to 6G and will not be repeated here. Method 1000 then proceeds to operation 1008, in which a first isolation layer surrounding semiconductor body 606 and the gate structure, a first surface and at least part of a second surface of the source/drain are exposed from the first isolation layer, the second surface is vertical to the first surface.

As illustrated in FIG. 7A, a recessed dielectric plug 740 is formed by etching at least part of dielectric plug 640 to expose at least part of the side surfaces of source/drain 624. Dielectric plug 640 cannot be removed completely to avoid short circuits between source/drain 624 and gate electrode 616. The thickness of recessed dielectric plug 740 is the distance between silicide 762 and gate electrode 616. The thickness of recessed dielectric plug 740 is larger than a threshold distance to keep the silicide isolated from the gate structure. The threshold distance is a minimum distance between silicide 762 and gate electrode 616 at which struck through is avoided. The threshold distance varies according to the feature size of semiconductor structure 700. For example, threshold distance is larger than half of the length of gate electrode 616.

Referring to FIG. 10, method 1000 the proceeds operations 1010, in which a silicide is formed on the first surface and at least part of the at least one second surface of the source/drain.

FIGS. 7A-7E illustrate an implementation in which an epitaxial structure 760 is formed before silicide is formed. As illustrated in FIG. 7B, epitaxial structure 760 is formed based on the top surface and at least part of the side surfaces of source/drain 624 through CVD, PVD, ALD, or any combination thereof. In a CVD process, for example, when the crystal plane orientations used for epitaxy growth are (111), (110), and (100), the resulting shapes of the epitaxially grown epitaxial structures 760 are hexagonal, trapezoidal, and rectangular, respectively. It is noted that the crystal plane orientation of the top surface is different from the crystal plane orientation of the side surface of source/drain 624. Thus, it is more complex to generate epitaxial structures 760 with a desired shape and size compared with FIG. 6K. With the additional side surfaces of source/drain 624 as a basement for growing epitaxial structure, it is easier to form an epitaxial structure having a larger area than source/drain 624. For example, in FIG. 7B, a rectangular epitaxial structure is designed to form a cuboid epitaxial structure. It is understood that epitaxial structures 760 can be any suitable shape and size as long as a projection of epitaxial structures 760 on silicon substrate 602 is larger than a projection of source/drain 624 on silicon substrate 602. For example, trapezoid or other irregular shapes also work for the present disclosure.

After epitaxial structures 760 are formed, a silicide 762 is formed based on epitaxial structure 760 to cover epitaxial structures 760, as illustrated in FIG. 7C. To form silicide 762, a first step is to deposit a layer of metal (such as Ti, Co, and NiPt) on epitaxial structures 660 using PVD. Then, two rapid thermal annealing (RTA) processes and one selective wet etching treatment are performed to form silicide 762 on the exposed surface of epitaxial structures 760. Metal silicides, including TiSi₂, CoSi₂, and NiPtSi, are formed. Metals such as Ti, Co, or NiPt will not react with the dielectric material, i.e., first isolation layer 742, to form metal silicide. They will only react with the epitaxial structures 760 in direct contact to form metal silicide. Silicide 762 can reduce the square resistance and contact resistance of epitaxial structures 760.

In this embodiment, two RTA processes are required to form silicide 762, taking the Ti-Silicide process as an example. First, a layer of Ti film is deposited, followed by a layer of TiN film covering the Ti film. The purpose of depositing the TiN film is to prevent Ti from flowing during rapid thermal annealing. The temperature of the first RTA is relatively low, only 450˜650° C., at which Ti reacts with the silicon in epitaxial structures 760 to form a high-resistance metal silicide Ti₂Si, which has a body-centered tetragonal crystal structure (C49 phase). Ti will not react with silicon dioxide to generate metal silicide, so selective wet etching can be used to remove the surface TiN film and the Ti film that does not react with silicon dioxide. The second RTA has a high temperature, at least 750° C., and some process platforms require as high as 950° C. The second RTA can convert the high-resistance metal silicide Ti₂Si in the C49 phase into the low-resistance metal silicide TiSi₂ in the face-centered orthorhombic crystal structure (C54 phase). TiSi₂ has good thermodynamic properties and is very stable. If only one RTA is used to generate low-resistance metal silicide TiSi₂, the process temperature of this step will be very high. In a high-temperature environment, silicon can diffuse along the grain boundaries of TiSi₂, causing excessive growth of TiSi₂ on the silicon dioxide boundary, which cannot be removed by wet etching, leading to a short circuit.

The thickness of the silicide is positively related to durations of the first RTA processes. The longer the RTA process lasts, the more silicon will be consumed, and the thicker the silicide will be. FIG. 7C illustrates a silicide 762 formed under a first RTA duration, and FIG. 7D illustrates a silicide 792 formed under a prolonged first RTA duration. In FIG. 7C, the silicon of the epitaxial structure 760 is consumed to form silicide 762. In FIG. 7D, as the first RTA process is prolonged, at least part of the silicon of source/drain 518 is consumed to react with the metal Ti to form silicide 792 after the silicon of epitaxial structure 760 is depleted. Silicide 792 has a bigger volume than silicide 762. By adjusting the duration of the first RTA process, the thickness and shape of the silicide 762 can be controlled precisely to get a desired thickness.

As illustrated in FIG. 7E, after silicide 762 is formed, a second isolation layer 764 is formed to surround silicide 762, and the top surface of silicide 762 is exposed from second isolation layer 764 so that second isolation layer 764 aligns with silicide 762. After silicide 762 is formed, a landing layer is formed to cover the silicide, then a through hole on the landing layer is formed to expose the silicide. The area of a cross-section of the through hole is larger than or equal to an area of a second top surface of the silicide. Then a source/drain contact is formed in touch with the silicide through a metal contact formed in the through hole. The process after silicide 762 is formed is the same as method 900 with respect to FIGS. 6M to 6P and will not be repeated.

FIG. 7G and FIG. 7H illustrate another implementation according to method 1000, in which the order of forming the second isolation layer 764 and a silicide 772. Referring to FIGS. 7G and 7H, second isolation layer 764 forms before silicide 772 to surround epitaxial structure 760, so that all the side surfaces of epitaxial structure 760 are covered by second isolation layer 764 and only the top surface of epitaxial structure 760 is exposed outside. Therefore, silicide 772 can only be formed on the top surface of epitaxial structure 760, and the distance between silicide 772 of two adjacent transistors in the present implementation is larger than the distance between silicide 762 of two adjacent transistors in the above-described implementation, as shown in FIG. 7E. In this way, a short circuit caused by the possible contact of silicide between two adjacent transistors is avoided.

FIGS. 8A and 8B illustrate an implementation in which epitaxial structures are eliminated to simplify the manufacturing process. As illustrated in FIG. 8A, a recessed dielectric plug 840 is formed by etching at least part of dielectric plug 640 to expose at least part of the side surfaces of source/drain 624. Dielectric plug 640 cannot be removed completely to avoid short circuits between source/drain 624 and gate electrode 616. The thickness of recessed dielectric plug 840 is a distance between silicide 862 and gate electrode 616. The thickness of recessed dielectric plug 840 is larger than a threshold distance to keep the silicide isolated from the gate structure. The threshold distance is a minimum distance between silicide 862 and gate electrode 616 at which struck through is avoided. The threshold distance varies according to the feature size of semiconductor structure 800. For example, the threshold distance is larger than half of the length of gate electrode 616.

After at least part of the side surfaces of source/drain 624 is exposed, a silicide 862 is formed based on the exposed the side surfaces of source/drain 624 as illustrated in FIG. 8B. To form silicide 862, and a first step is to deposit a layer of metal (such as Ti, Co, and NiPt) on source/drain 624 using PVD. Then, two rapid thermal annealing (RTA) processes and one selective wet etching treatment are performed to form silicide 862 on the exposed surface of source/drain 624. Metal silicides, including TiSi₂, CoSi₂, and NiPtSi, are formed. Metals such as Ti, Co, or NiPt will not react with the dielectric material, i.e., first isolation layer 842, to form metal silicide. They will only react with the source/drain 624 in direct contact to form metal silicide. Silicide 862 can reduce the square resistance and contact resistance of source/drain 624. The method and process for forming silicide 862 are the same as the above-described implementations and will not be repeated here.

By increasing the area of the source/drain for forming the silicide in a three-dimensional semiconductor device, the linewidth of silicide formed on source/drain in the present semiconductor structure is improved significantly. Thereby, silicide can be used in manufacturing processes having a small feature size. According to some aspects of the present disclosure, an epitaxial structure with a larger surface area is formed on the source/drain to increase the linewidth of the silicide. According to some aspects of the present disclosure, in addition to the top surface of the source/drain, the area where silicide is formed is expanded to include the side surfaces of the source/drain to increase the linewidth of the silicide. With the application of the present disclosure, the limitations of the feature size of the silicide processes are eliminated.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations but should be defined only in accordance with the following claims and their equivalents.

What is claimed is:

1. A semiconductor structure, comprising a vertical transistor, the vertical transistor comprising:
a semiconductor body extending in a first direction, the semiconductor body comprising a source/drain at one end of the semiconductor body;
a gate structure coupled to at least one side of the semiconductor body, the gate structure comprising a gate dielectric and a gate electrode; and
a silicide, wherein
at least part of the silicide is above the source/drain; and
an area of the silicide is larger than an area of a first surface of the source/drain, the first surface being vertical to the first direction.

2. The semiconductor structure of claim 1, wherein the silicide at least partially covers at least one second surface of the source/drain, the at least one second surface being vertical to the first surface.

3. The semiconductor structure of claim 1, further comprising an epitaxial structure formed between the source/drain and the silicide.

4. The semiconductor structure of claim 3, further comprising a first isolation layer surrounding the semiconductor body, wherein
the first surface of the source/drain is exposed from the first isolation layer; and
the epitaxial structure covers the first surface of the source/drain.

5. The semiconductor structure of claim 3, further comprising a first isolation layer surrounding the semiconductor body, wherein
the first surface and at least part of a second surface of the source/drain is exposed from the first isolation layer; and
the epitaxial structure covers the first surface and at least part of the second surface of the source/drain.

6. The semiconductor structure of claim 3, further comprising a second isolation layer surrounding the epitaxial structure, wherein
a first top surface of the epitaxial structure is exposed from the second isolation layer; and
the silicide covers the first top surface of the epitaxial structure.

7. The semiconductor structure of claim 1, further comprising a second isolation layer surrounding the silicide, wherein a second top surface of the silicide is exposed from the second isolation layer.

8. The semiconductor structure of claim 1, wherein
the silicide is isolated from the gate structure; and
a minimal distance between the silicide and the gate structure is larger than a threshold distance.

9. The semiconductor structure of claim 1, further comprising:
a landing layer covered the silicide; and
a metal contact extended through the landing layer and in contact with a second top surface of the silicide, wherein an area of a surface of the metal contact in touch with the silicide is smaller than or equal to the area of the second top surface of the silicide.

10. The semiconductor structure of claim 1, wherein the silicide comprises elements of Titanium (Ti), Cobalt (Co), or nickel platinum alloy (NiPt).

11. The semiconductor structure of claim 10, wherein the silicide comprises titanium disilicide (TiSi₂) in a face-centered orthorhombic structure (C54 phase).

12. A semiconductor system, comprising:
a semiconductor structure comprising a plurality of vertical transistors; and
a memory controller coupled to the semiconductor structure and configured to control the semiconductor structure, wherein
each vertical transistor of at least part of the plurality of vertical transistors comprises:
a semiconductor body extending in a first direction, the semiconductor body comprising a source/drain at one end of the semiconductor body;
a gate structure coupled to at least one side of the semiconductor body, the gate structure comprising a gate dielectric and a gate electrode; and
a silicide, wherein
at least part of the silicide is above the source/drain; and
an area of the silicide is larger than an area of a first surface of the source/drain, the first surface being vertical to the first direction.

13. A method for forming a semiconductor structure, comprising:
forming a semiconductor body of the semiconductor structure extending in a first direction from a substrate;
forming a gate structure on at least one side of the semiconductor body;
forming a source/drain at a distal end of the semiconductor body away from the substrate;
forming a first isolation layer surrounding the semiconductor body and the gate structure; and
forming a silicide; wherein
at least part of the silicide is above the source/drain; and
an area of the silicide is larger than an area of a first surface of the source/drain, the first surface being vertical to the first direction.

14. The method of claim 13, wherein a first surface and at least part of a second surface of the source/drain are exposed from the first isolation layer, the second surface being vertical to the first surface, and the silicide is formed on the first surface and at least part of a second surface of the source/drain.

15. The method of claim 14, further comprising:
after forming the silicide, forming a second isolation layer surrounding the silicide, wherein a first surface of the silicide is exposed from the second isolation layer.

16. The method of claim 14, wherein forming the silicide comprises:
depositing a metal layer covering the first surface and the at least part of the second surface of the source/drain exposed from the first isolation layer; and
heating the metal layer to form the silicide.

17. The method of claim 16, wherein heating the metal layer comprises:
depositing a metal nitride on the metal layer;
performing a first rapid thermal annealing (RTA) on the metal layer and the metal nitride at a first temperature lower than a threshold temperature; and
performing a second RTA on the metal layer at a second temperature higher than the threshold temperature.

18. The method of claim 13, a first surface of the source/drain being exposed from the first isolation layer, and the method further comprising:
growing an epitaxial structure from the first surface of the source/drain before forming the silicide; wherein
an area of a first surface of the epitaxial structure is larger than an area of the first surface of the source/drain; and
the silicide is formed based on the epitaxial structure.

19. The method of claim 18, further comprising:
after forming a first isolation layer, etching the first isolation layer to expose at least part of a second surface of the source/drain, the second surface of the source/drain being vertical to the first surface of the source/drain; wherein
the epitaxial structure is grown from the at least part of the second surface of the source/drain exposed from the first isolation layer.

20. The method of claim 18, wherein forming the silicide comprises:
forming a second isolation layer covering the epitaxial structure, the second isolation layer aligning with the epitaxial structure, at least a first surface of the epitaxial structure is exposed from the second isolation layer;
depositing a metal layer at least covering the first surface of the epitaxial structure exposed from the second isolation layer; and
heating the metal layer to form the silicide.
